(19) United States
(12) Patent Application Publication
(10) Pub. No.: US 2013/0082230 A1
(43) Pub. Date: Apr. 4, 2013

(54) METHOD OF MANUFACTURING NONVOLATILE MEMORY ELEMENT, AND NONVOLATILE MEMORY ELEMENT

(71) Applicants: Koji Katayama, Nara (JP); Takeshi Takagi, Kyoto (JP)

(72) Inventors: Koji Katayama, Nara (JP); Takeshi Takagi, Kyoto (JP)

(21) Appl. No.: 13/703,533

(22) PCT Filed: Sep. 30, 2011
(86) PCT No.: PCT/JP2011/005533

§ 371 Date: Dec. 11, 2012

(30) Foreign Application Priority Data
Oct. 1, 2010 (JP) 2010-223818

(51) Int. Cl. H01L 45/00

(52) U.S. Cl. CPC H01L 45/16; H01L 45/145
USPC 257/4; 438/382

(57) ABSTRACT

A variable resistance nonvolatile memory element manufacturing method includes: forming a first electrode on a substrate; forming a first metal oxide layer having a predetermined oxygen content atomic percentage on the first electrode; forming, in at least one part of the first metal oxide layer, a modified layer higher in resistance than the first metal oxide layer, by oxygen deficiency reduction; forming a second metal oxide layer lower in oxygen content atomic percentage than the first metal oxide layer, on the modified layer; and forming a second electrode on the second metal oxide layer. A variable resistance layer includes the first metal oxide layer having the modified layer and the second metal oxide layer, connects to the first electrode and the second electrode, and changes between high and low resistance states according to electrical pulse polarity.

### TECHNICAL FIELD

The present invention relates to a method of manufacturing a variable resistance nonvolatile memory element that changes in resistance value according to an applied electrical signal.

### BACKGROUND ART

With advances in digital technology, electronic appliances such as mobile information appliances and home information appliances are increasingly sophisticated in recent years. Such sophistication of electronic appliances is accompanied by rapid miniaturization and acceleration of semiconductor elements used. In particular, large-capacity nonvolatile memories, represented by flash memories, are finding rapidly expanding use. Moreover, nonvolatile memory devices including variable resistance nonvolatile memory elements are under research and development as new, next-generation nonvolatile memories that can replace flash memories. A variable resistance nonvolatile memory element mentioned here is such an element that has a property of reversibly changing in resistance value according to an applied electrical signal and enables information corresponding to the resistance value to be written in a nonvolatile manner.

For example, the variable resistance nonvolatile memory element has a structure in which a variable resistance layer comprising a variable resistance material is placed between a pair of electrodes, as disclosed in Patent Literature (PTL) 1. There are two main types of the variable resistance nonvolatile memory element: bipolar type and unipolar type, according to differences in electrical characteristics.

A nonvolatile memory element of bipolar type (hereafter referred to as “bipolar type element”) is an element of a type that uses voltages of different polarities as voltages for changing a resistance state between a high resistance state and a low resistance state.

A nonvolatile memory element of unipolar type (hereafter referred to as “unipolar type element”) is an element of a type that uses voltages of the same polarity as voltages for changing the resistance state. In the unipolar type element, for example, a single transition metal oxide such as nickel oxide (NiOₓ), or titanium oxide (TiOₓ) is used as the variable resistance material. Of the above-mentioned two types of nonvolatile memory elements, the unipolar type element has the following problems. In the unipolar type element using a transition metal oxide such as NiOₓ, the variable resistance material can be changed from the high resistance state to the low resistance state by a short electrical pulse of about 100 ns, as disclosed in Non Patent Literature (NPL) 1. To change the variable resistance material from the low resistance state to the high resistance state, however, a long pulse of the order of microseconds is needed, which makes it difficult to accelerate operations. Besides, in the unipolar type element, the resistance state is hard to be changed immediately after the structure in which the variable resistance layer is placed between the upper and lower electrodes is formed.

Typically, in operations of the variable resistance nonvolatile memory element, an initial breakdown step similar to dielectric breakdown of an insulator needs to be performed until a steady state of resistance change is reached. In the initial breakdown step, a voltage higher than a voltage required for a steady resistance change is applied to the element. This hinders low voltage operations. Thus, the unipolar type element has a demerit of requiring a high voltage for the initial breakdown step.

### CITATION LIST

### Patent Literature

### [PTL 1]

International Patent Application Publication No. 2007/013174

### Non Patent Literature

### [NPL 1]

I. G. Baek et al., Tech. Digest IEDM 2004, p. 587

### SUMMARY OF INVENTION

### Technical Problem

The initial breakdown step hinders low voltage operations of the nonvolatile memory element, as described above. Especially when the initial breakdown step is performed in a state where a load resistance element such as a diode or a transistor is connected to the variable resistance nonvolatile memory element, there are cases where, if a large current flows upon initial breakdown, an effective applied voltage to the nonvolatile memory element decreases due to an IR drop (voltage drop) in the load resistance element, as a result of which initial breakdown fails to occur. To ensure that initial breakdown occurs, it is necessary to increase the applied voltage so as to compensate for the IR drop in the load resistance element.

For example, in the unipolar type element, the variable resistance layer comprises a comparatively thick high-oxygen-concentration metal oxide of 10 nm or more. Accordingly, the current upon breakdown is extremely small though the breakdown voltage of the element alone is high, and so it is hardly necessary to increase the applied voltage in order to compensate for the IR drop in the load resistance element.

In the bipolar type element whose variable resistance layer has a stack structure of a high resistance layer and a low resistance layer, however, the high resistance layer has a small film thickness. Accordingly, the current upon breakdown is large though the breakdown voltage of the element alone is low. This can pose a problem as there is a need to increase the applied voltage in order to compensate for the IR drop in the load resistance element.

The present invention has been made in view of such circumstances, and has an object of providing a method of manufacturing a variable resistance nonvolatile memory element capable of reducing a voltage upon initial breakdown.

### Solution to Problem

To solve the problems stated above, a method of manufacturing a nonvolatile memory element according to one aspect of the present invention includes: forming a first electrode on a substrate; forming a high resistance layer on the first electrode, the high resistance layer comprising a transition metal oxide;

modifying at least one part of the high resistance layer to a modified layer by reducing an oxygen deficiency of the at least one part, the modified layer having a higher oxygen content atomic percentage than the high resistance layer; forming a low resistance layer on the modified layer, the low resistance layer comprising a transition metal oxide having a lower oxygen content atomic percentage than the high resistance layer; and forming a second electrode on the low resistance layer.

According to this manufacturing method, a current flowing in a variable resistance nonvolatile memory element upon initial breakdown can be reduced by controlling a state of an interface between a first oxide layer and a second oxide layer.

To solve the problems stated above, a method of manufacturing a nonvolatile memory element according to one aspect of the present invention includes: forming a first electrode on a substrate; forming a low resistance layer on the first electrode, the low resistance layer comprising a transition metal oxide; forming a high resistance layer on the low resistance layer, the high resistance layer comprising a transition metal oxide having a higher oxygen content atomic percentage than the low resistance layer; modifying at least one part of the high resistance layer to a modified layer by reducing an oxygen deficiency of the at least one part, the modified layer having a higher oxygen content atomic percentage than the high resistance layer; and forming a second electrode on the high resistance layer or the modified layer.

Preferably, the modifying includes modifying the whole high resistance layer to the modified layer.

Moreover, the modifying may include modifying a part of the high resistance layer to the modified layer, wherein the nonvolatile memory element includes a variable resistance layer including: the low resistance layer; the high resistance layer; and the modified layer located between the low resistance layer and the high resistance layer.

Preferably, the modifying includes oxidizing the at least one part of the high resistance layer.

Here, the oxidizing may include plasma oxidizing the at east one part of the high resistance layer.

Preferably, the nonvolatile memory element changes between a high resistance state and a low resistance state according to an applied electrical pulse.

Moreover, the high resistance layer may comprise a tantalum oxide having a composition expressed as TaOₓ where 2.1≦x, wherein the low resistance layer comprises a tantalum oxide having a composition expressed as TaO_{y} where 0.8≦y≦1.9.

Preferably, the variable resistance layer has a thickness not less than 5 nm and not more than 1 μm, and the high resistance layer has a thickness not less than 1 nm and not more than 8 nm,

Moreover, the first electrode (or the second electrode) may have a flat surface with no projection of 2 nm or larger, in an interface of the first electrode (or the second electrode) with the high resistance layer or the modified layer. For example, the first electrode (or the second electrode) may comprise platinum with a film thickness not less than 1 nm and not more than 8 nm, and the first electrode or the second electrode may comprise iridium,

Moreover, the nonvolatile memory element may be manufactured to further include a current steering element that is electrically connected to the first electrode or the second electrode. For example, the current steering element may be a transistor, and the current steering element may be a diode.

To solve the problems stated above, a method of manufacturing a nonvolatile memory element according to one aspect of the present invention includes: a variable resistance layer that changes between a high resistance state and a low resistance state according to an applied electrical pulse; and a first electrode and a second electrode that are connected to the variable resistance layer, wherein the variable resistance layer includes: a high resistance layer comprising a transition metal oxide; a low resistance layer comprising a transition metal oxide having a lower oxygen content atomic percentage than the high resistance layer; and a modified layer located between the high resistance layer and the low resistance layer, and comprising a transition metal oxide having a higher oxygen content atomic percentage than the high resistance layer.

To solve the problems stated above, a method of manufacturing a nonvolatile memory element according to one aspect of the present invention is a method of manufacturing a nonvolatile memory element including: a variable resistance layer that comprises a metal oxide and changes between a high resistance state and a low resistance state according to an applied electrical pulse; and a first electrode and a second electrode that are connected to the variable resistance layer, the method including: forming the first electrode on a substrate; forming a high resistance layer on the first electrode, the high resistance layer comprising a transition metal oxide having a predetermined oxygen content atomic percentage; forming an intermediate layer on the high resistance layer, the intermediate layer comprising a transition metal oxide that has an oxygen deficiency reduced from an oxygen deficiency of the transition metal oxide of the high resistance layer and has a higher oxygen content atomic percentage than the high resistance layer; forming a low resistance layer on the intermediate layer, the low resistance layer comprising a transition metal oxide having a lower oxygen content atomic percentage than the high resistance layer; and forming the second electrode on the low resistance layer, wherein the variable resistance layer includes the high resistance layer, the intermediate layer, and the low resistance layer.

To solve the problems stated above, a method of manufacturing a nonvolatile memory element according to one aspect of the present invention is a method of manufacturing a nonvolatile memory element including: a variable resistance layer that comprises a metal oxide and changes between a high resistance state and a low resistance state according to an applied electrical pulse; and a first electrode and a second electrode that are connected to the variable resistance layer, the method including: forming the first electrode on a substrate; forming a low resistance layer on the first electrode, the low resistance layer comprising a transition metal oxide having a predetermined oxygen content atomic percentage; forming an intermediate layer on the low resistance layer, the intermediate layer comprising a transition metal oxide having a higher oxygen content atomic percentage than the low resistance layer; forming a high resistance layer on the intermediate layer, the high resistance layer comprising a transition metal oxide having a higher oxygen content atomic percentage than the low resistance layer and a lower oxygen content atomic percentage than the intermediate layer; and forming the second electrode on the high resistance layer, wherein the variable resistance layer includes the high resistance layer, the intermediate layer, and the low resistance layer.

To solve the problems stated above, a nonvolatile memory element according to one aspect of the present invention includes; a variable resistance layer that changes between a high resistance state and a low resistance state according to an applied electrical pulse; and a first electrode and a second electrode that are connected to the variable resistance layer, wherein the variable resistance layer includes: a high resistance layer comprising a transition metal oxide; a low resistance layer comprising a transition metal oxide having a lower oxygen content atomic percentage than the high resistance layer; and an intermediate layer located between the high resistance layer and the low resistance layer, and comprising a transition metal oxide having a higher oxygen content atomic percentage than the high resistance layer,

### Advantageous Effects of Invention

According to the present invention, a method of manufacturing a variable resistance nonvolatile memory element capable of reducing a voltage upon initial breakdown can be provided. Even when a load resistor is connected to a variable resistance nonvolatile memory element such as a variable resistance element, there is no need to increase a voltage for an initial breakdown step, so that a high-density memory cell array can be realized without an increase in size of a transistor and the like.

### BRIEF DESCRIPTION OF DRAWINGS

FIG. 1 is a schematic diagram showing an example of a structure of a variable resistance element according to the present invention.

FIG. 2A is a transmission electron microscope (TEM) photograph showing a cross section of a nonvolatile memory element in which oxygen-deficient tantalum oxide is used in a variable resistance layer.

FIG. 2B is a transmission electron microscope (TEM) photograph showing a cross section of a nonvolatile memory element in which oxygen-deficient tantalum oxide is used in a variable resistance layer.

FIG. 3A is a transmission electron microscope (TEM) photograph showing a cross section of a nonvolatile memory element in which oxygen-deficient hafnium oxide is used in a variable resistance layer.

FIG. 3B is a transmission electron microscope (TEM) photograph showing a cross section of a nonvolatile memory element in which oxygen-deficient hafnium oxide is used in a variable resistance layer.

FIG. 4A is a transmission electron microscope (TEM) photograph showing an element cross section in an example.

FIG. 4B is a transmission electron microscope (TEM) photograph showing an element cross section in the example.

FIG. 4C is a transmission electron microscope (TEM) photograph showing an element cross section in the example.

FIG. 5 is a diagram showing results of plotting an initial resistance of each of elements A, B, and C against a film thickness of a Pt layer in the example.

FIG. 6A is a diagram showing resistance change operations of the element A in the example.

FIG. 6B is a diagram showing resistance change operations of the element B in the example.

FIG. 6C is a diagram showing resistance change operations of the element C in the example.

FIG. 7A is a diagram showing relations between a converted film thickness of the Pt layer and binding energy in the example.

FIG. 7B is a diagram plotting a binding energy value of a main peak of each spectrum in FIG. 7A against the film thickness of the Pt layer.

FIG. 8A is a diagram for describing a method of manufacturing the variable resistance element according to the present invention.

FIG. 8B is a diagram for describing the method of manufacturing the variable resistance element according to the present invention.

FIG. 8C is a diagram for describing the method of manufacturing the variable resistance element according to the present invention.

FIG. 8D is a diagram for describing the method of manufacturing the variable resistance element according to the present invention,

FIG. 8E is a diagram for describing the method of manufacturing the variable resistance element according to the present invention.

FIG. 8F is a diagram for describing the method of manufacturing the variable resistance element according to the present invention.

FIG. 8G is a diagram for describing the method of manufacturing the variable resistance element according to the present invention.

FIG. 9 is a diagram showing results of examining changes in density (refractive index), film thickness, and surface roughness of samples by X-ray reflectivity profile measurement.

FIG. 10A is a diagram showing measurement results of a first tantalum oxide layer in a modification step by X-ray photoelectron spectroscopy (XPS).

FIG. 10B is a diagram showing measurement results of the first tantalum oxide layer in the modification step by X-ray photoelectron spectroscopy (XPS).

FIG. 11 is a schematic diagram showing a structure of a variable resistance element as a comparative sample in the example.

FIG. 12 is a diagram plotting an initial resistance value against a film thickness of the first tantalum oxide layer.

FIG. 13A is a diagram showing changes in resistance value of a variable resistance element 10,

FIG. 13B is a diagram showing changes in resistance value of a variable resistance element 20,

FIG. 14A is a diagram showing current-voltage characteristics of the variable resistance element 10 until hard breakdown is reached.

FIG. 14B is a diagram showing current-voltage characteristics of the variable resistance element 20 until hard breakdown is reached.

FIG. 15A is a diagram showing current-voltage characteristics of the variable resistance element 10 until hard breakdown is reached.

FIG. 15B is a diagram showing current-voltage characteristics of the variable resistance element 20 until hard breakdown is reached.

FIG. 16A is a diagram showing relations of a soft breakdown voltage and a soft breakdown current of the variable resistance element 10 with the film thickness of the first tantalum oxide layer.

FIG. 16B is a diagram showing relations of a soft breakdown voltage and a soft breakdown current of the variable resistance element 20 with the film thickness of the first tantalum oxide layer,

FIG. 17A is a diagram showing a hard breakdown voltage and a hard breakdown current of the variable resistance element 10 against the film thickness of the first tantalum oxide layer.

FIG. 17B is a diagram showing a hard breakdown voltage and a hard breakdown current of the variable resistance element 20 against the film thickness of the first tantalum oxide layer.

FIG. 18 is a diagram showing resistance change operations of a variable resistance element of a sample 3.

FIG. 19 is a diagram showing resistance change operations of a variable resistance element of a comparative sample 2.

### DESCRIPTION OF EMBODIMENTS

The following describes a preferred embodiment of the present invention with reference to drawings.

### [Structure of Variable Resistance Element]

A structure of a variable resistance element according to the present invention is described first.

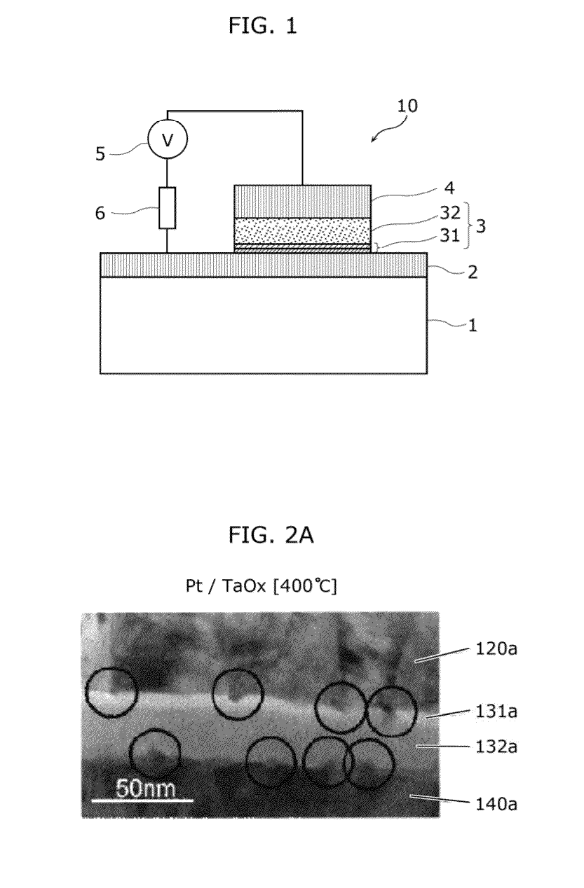

FIG. 1 is a schematic diagram showing an example of a structure of a variable resistance element according to the present invention. A variable resistance element 10 shown in FIG. 1 is a nonvolatile memory element including: a variable resistance layer that comprises a metal oxide and changes between a high resistance state and a low resistance state according to a polarity of an applied electrical pulse; and a first electrode and a second electrode that are connected to the variable resistance layer. The variable resistance element 10 includes: a substrate 1; a first electrode 2 formed on the substrate 1; a metal oxide layer 3 formed on the first electrode 2; and a second electrode 4 formed on the metal oxide layer 3. The metal oxide layer 3 may have a stack structure of a first metal oxide layer 31 and a second metal oxide layer 32. The first metal oxide layer 31 has a higher oxygen content atomic percentage than the second metal oxide layer 32. This makes it possible to selectively induce a resistance change phenomenon in the first metal oxide layer 31. A metal constituting the first metal oxide layer 31 and the second metal oxide layer 32 is preferably a transition metal such as tantalum, hafnium, zirconium, or the like. The use of such a transition metal oxide as a variable resistance layer contributes to stable operations. The variable resistance element 10 may use, for example, a transistor or a diode as a current steering element. When the current steering element is in a conductive state (on), the current steering element acts as a load resistor 6 for the variable resistance element 10.

The substrate 1 is composed of a silicon substrate, as an example.

The first electrode 2 and the second electrode 4 are both physically and electrically connected to the metal oxide layer 3. In the case where the variable resistance element to includes the load resistor 6, the load resistor 6 is connected in series with at least one of the first electrode 2 and the second electrode 4. The first electrode 2 and the second electrode 4 may have the same size.

For example, the first electrode 2 and the second electrode 4 comprise one or more materials out of Au (gold), Pt (platinum), Ir (iridium), Pd (palladium), Cu (copper), Ag (silver), TaN (tantalum nitride), Ta (tantalum), Ti (titanium), and TiN (titanium nitride).

In detail, the first electrode 2 is placed in contact with the first metal oxide layer 31. The first electrode 2 comprises any of Au, Pt, Ir, Pd, Cu, Ag, and the like, as an example. In the case of using Ta as the transition metal constituting the metal oxide layer 3, the first electrode 2 preferably comprises one or more materials that are higher in standard electrode potential than Ta. Meanwhile, the second electrode 4 preferably comprises any of materials (e.g. W (tungsten), Ni (nickel), Ta, TaN, and the like) that are lower in standard electrode potential than the material(s) constituting the first electrode 2. In other words, when the standard electrode potential of the first electrode 2 is denoted by V₁, the standard electrode potential of the second electrode 4 by V₂, and the standard electrode potential of tantalum as V_{Ta}, it is preferable to satisfy relations V_{Ta}<V₁ and V₂<V₁. This makes it possible to stably induce a resistance change phenomenon in the first metal oxide layer 31 which is in contact with the first electrode 2.

The first electrode 2 preferably comprises Ir, or Pt with a film thickness not less than 1 nm and not more than 23 nm. In the case where the first electrode 2 comprises Pt, the film thickness is more preferably not less than 1 nm and not more than 13 nm, still more preferably not less than 1 nm and not more than 10 nm, and most preferably not less than 1 nm and not more than 8 nm,

The metal oxide layer 3 is a variable resistance layer formed by stacking a plurality of metal oxide layers (tantalum oxide layers here) that differ in oxygen content atomic percentage. In detail, the metal oxide layer 3 is formed by stacking the first metal oxide layer 31 and the second metal oxide layer 32. The first metal oxide layer 31 has a higher oxygen content atomic percentage than the second metal oxide layer 32. Preferably, when the first metal oxide layer 31 has a composition expressed as TaOₓ and the second metal oxide layer 32 has a composition expressed as TaO_{y}, x is not less than 2.1 and y is not less than 0.8 and not more than 1.9. The metal oxide layer 3 may be a transition metal oxide layer other than a tantalum oxide layer. As an example, in the case where the metal oxide layer 3 is formed by stacking a first hafnium oxide layer (first metal oxide layer 31) and a second hafnium oxide layer (second metal oxide layer 32), it is desirable that, when the first hafnium oxide layer has a composition expressed as HfOₓ and the second hafnium oxide layer has a composition expressed as HfO_{y}, x is more than 1.8 and y is not less than 0.9 and not more than 1.6. As another example, in the case where the metal oxide layer 3 is formed by stacking a first zirconium oxide layer (first metal oxide layer 31) and a second zirconium oxide layer (second metal oxide layer 32), it is desirable that, when the first zirconium oxide layer has a composition expressed as ZrOₓ and the second zirconium oxide layer has a composition expressed as ZrO_{y}, x is more than 1.9 and y is not less than 0.9 and not more than 1.4. In the case where x and y are in the above-mentioned ranges, the resistance value of the metal oxide layer 3 can be stably changed at high speed. This will be described in detail later.

The metal oxide layer 3 has a thickness that is preferably not less than 10 nm, and is not more than 1 μm and preferably not more than 200 nm. When the thickness of the metal oxide layer 3 is not more than 1 μm, a change in resistance value is observed. A thickness not more than 200 nm is preferable because manufacture is facilitated in the case of using lithography in a patterning process, and also a voltage value of a voltage pulse necessary for changing the resistance value of the metal oxide layer 3 can be reduced. A thickness not less than 10 nm is preferable because the variable resistance element 10 is more reliably kept from breakdown upon voltage pulse application.

The first metal oxide layer 31 is a layer, in the metal oxide layer 3, where a resistance change phenomenon substantially occurs, and is a high resistance layer provided in order to protect the variable resistance element 10 from breakdown or writing due to charge-up or the like during manufacturing. In other words, the first metal oxide layer 31 has a very important role in achieving stable resistance change operations of the variable resistance element 10. In the case where the first metal oxide layer 31 comprises tantalum oxide, the thickness of the first metal oxide layer 31 is preferably about not less than 1 nm and not more than 8 nm. In the case where the first metal oxide layer 31 comprises hafnium oxide, the thickness of the first metal oxide layer 31 is preferably about not less than 4 nm and not more than 5 nm. In the case where the first metal oxide layer 31 comprises zirconium oxide, the thickness of the first metal oxide layer 31 is preferably about not less than 1 nm and not more than 5 nm. An excessively thick first metal oxide layer 31 is disadvantageous because an initial resistance value is too high, and an excessively thin first metal oxide layer 31 is equally disadvantageous because a stable resistance change cannot be achieved.

The variable resistance element 10 has the structure described above.

Moreover, a modified layer or an intermediate layer having a higher oxygen content atomic percentage (higher resistance) than the first metal oxide layer 31 is formed between the first metal oxide layer 31 (high resistance layer) and the second metal oxide layer 32 (low resistance layer). In detail, the modified layer is formed in at least one part of the first metal oxide layer 31, by performing modification that reduces an oxygen deficiency of the at least one part of the first metal oxide layer 31. The modified layer may be the whole first metal oxide layer 31 (high resistance layer). The intermediate layer is a layer formed on the first metal oxide layer 31 and having an oxygen deficiency reduced from that of the first metal oxide layer 31.

As mentioned above, the transition metal oxide (preferably oxide of Ta, Hf, Zr, or the like) is used as the material of the metal oxide layer 3, i.e. the variable resistance layer, in the variable resistance element 10. In particular, the second metal oxide layer 32 preferably comprises an oxygen-deficient transition metal oxide. The oxygen-deficient transition metal oxide is an oxide that is lower in oxygen content (atomic ratio: a proportion of the number of oxygen atoms to the total number of atoms) than an oxide having a stoichiometric composition. Typically, an oxide having a stoichiometric composition is an insulator or has a very high resistance. For example, in the case of Ta as a transition metal, Ta₂O₅ is an oxide having a stoichiometric composition, where a ratio (O/Ta) in the number of atoms between Ta and O is 2.5. Accordingly, oxygen-deficient Ta oxide has an O/Ta atomic ratio that is more than 0 and less than 2.5. In the present invention, the oxygen-deficient transition metal oxide is preferably oxygen-deficient Ta oxide. More preferably, the second metal oxide layer 32 has at least a stack structure formed by stacking a second tantalum-containing layer (second metal oxide layer 32) having a composition expressed as TaO_{y} (0<y<2.5) and a first tantalum-containing layer (first metal oxide layer 31) having a composition expressed as TaOₓ (y<x), as described earlier. One or more other layers such as a third tantalum-containing layer and a layer of another transition metal oxide may be provided according to need.

The following describes reasons why the above-mentioned film thickness ranges of the first electrode 2 are preferable.

### [Electrodes of Variable Resistance Element]

The first electrode 2 is an electrode in contact with the first metal oxide layer 31 having a higher oxygen content atomic percentage than the second metal oxide layer 32. By performing the below-mentioned modification process for the film of the first metal oxide layer 31 according to the present invention in a state where the first electrode 2 is an electrode having a flat surface without small projections that are for example not more than 2 nm, preferably not more than 1 nm, and more preferably not more than 0.5 nm, it is possible to not only reduce a breakdown voltage but also reduce variations in initial resistance. This advantageous effect is described in detail first,

It has hitherto been difficult to both improve reproducibility of electrical characteristics (in particular, initial resistance) and operational reliability (durability) and reduce the breakdown voltage in the initialization process. In detail, in terms of electrical characteristics and reliability, it is preferable that a flat electrode (first electrode 2) without small projections forms an interface with the first metal oxide layer 31 having a high initial resistance. However, the use of such an electrode has a problem that the initial resistance increases and the breakdown voltage in the initialization process increases because the breakdown voltage is uniformly applied to the first metal oxide layer 31 in the initialization process. In terms of reducing the breakdown voltage in the initialization process, on the other hand, an electrode with small projections is preferable. However, such an electrode cannot be employed because of a problem that it is difficult to attain desired electrical characteristics and ensure reliability.

In view of this, a predetermined modification process for the film of the first metal oxide layer 31 according to the present invention is performed to reduce the breakdown voltage in the initialization process while using a flat electrode (first electrode 2) without small projections that are for example not more than 2 nm, preferably not more than 1 nm, and more preferably not more than 0.5 nm. The problem of the increase of the breakdown voltage in the initialization process is solved in this way. That is, even in the case of using a flat electrode (first electrode 2) without small projections, the breakdown voltage can be reduced while ensuring desired electrical characteristics and reliability.

The first electrode 2 can be formed as a flat electrode without small projections, by using an Ir electrode as the first electrode 2 or by using a Pt electrode whose film thickness is not less than 1 nm and not more than 23 nm as the first electrode 2 as mentioned earlier. A smaller film thickness of the Pt electrode contributes to reduced stress, with it being possible to suppress the formation of projections in the interface. Accordingly, the film thickness of the Pt electrode (first electrode 2) is more preferably not less than 1 nm and not more than 13 nm, still more preferably not less than 1 nm and not more than 10 nm, and most preferably not less than 1 nm and not more than 8 nm.

These findings about the first electrode 2 result from the below-mentioned experiment conducted by the inventors of the present invention. Experimental results leading to the findings and considerations about the experimental results are described in Experiment 1 below.

### (Experiment 1)

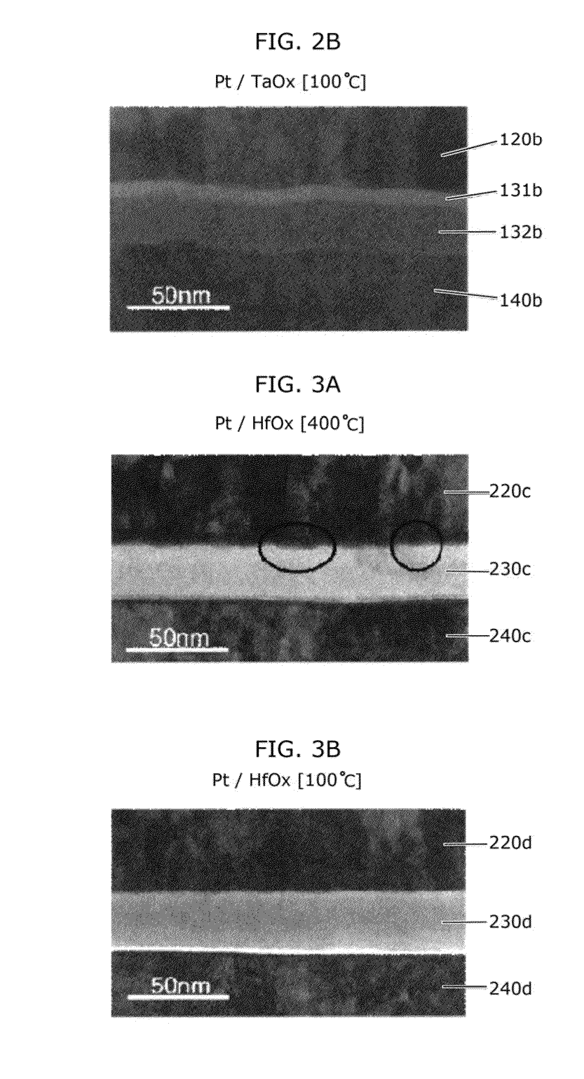

FIGS. 2A and 2B are each a transmission electron microscope (TEM) photograph showing a cross section of a nonvolatile memory element in which oxygen-deficient tantalum oxide is used in the variable resistance layer and Pt is used in the electrodes. FIG. 2A corresponds to the case where 400° C. is the maximum temperature in the process, and FIG. 2B corresponds to the case where 100° C. is the maximum temperature in the process.

In the element shown in FIG. 2A, a second oxygen-deficient tantalum oxide layer 132a of about 23 nm in film thickness, a first oxygen-deficient tantalum oxide layer 131a of about 8 nm in film thickness, and a first electrode layer 120a comprising a Pt layer of about 80 nm in film thickness are stacked in this order on a second electrode layer 140a comprising a Pt layer of about 50 nm in film thickness. The first oxygen-deficient tantalum oxide layer 131a is higher in oxygen content (substantially Ta₂O₅ in composition) than the second oxygen-deficient tantalum oxide layer 132a. The element shown in FIG. 2A was produced using a process technology relating to semiconductor device manufacturing, with the maximum temperature in the heating step in the process being about 400° C. 400° C. is a temperature necessary in formation (sintering) of electrode wires comprising, for example, copper or aluminum.

As is clear from a close study of FIG. 2A, when heated at 400° C., small projections (circled parts in the photograph, 3 nm or more in size) comprising Pt were formed from the electrode toward the variable resistance layer. In detail, small projections comprising Pt were formed from the second electrode layer 140a in an upward direction in the photograph (direction toward the second oxygen-deficient tantalum oxide layer 132a). Small projections comprising Pt were also formed from the first electrode layer 120a in a downward direction in the photograph (direction toward the first oxygen-deficient tantalum oxide layer 131a),

Most of these projections extend from around grain boundaries of the upper and lower Pt layers. It is especially to be noted that the projections extending from the first electrode layer 120a reach approximately half the thickness of the first oxygen-deficient tantalum oxide layer 131a.

The manufacturing method of the element shown in FIG. 2B is the same as that of the element shown in FIG. 2A. That is, in the element shown in FIG. 2B, a second oxygen-deficient tantalum oxide layer 132b of about 23 nm in film thickness, a first oxygen-deficient tantalum oxide layer 131b of about 8 nm in film thickness, and a first electrode layer 120b comprising a Pt layer of about 80 nm in film thickness are stacked in this order on a second electrode layer 140b comprising a Pt layer of about 50 nm in film thickness. The first oxygen-deficient tantalum oxide layer 131b is higher in oxygen content (substantially Ta₂O₅ in composition) than the second oxygen-deficient tantalum oxide layer 132b. Meanwhile, the maximum temperature in the heating step in the process is limited to about 100° C.

Projections comprising Pt were not formed in this element, as shown in FIG. 2B. That is, projections from the first electrode layer 120b toward the first oxygen-deficient tantalum oxide layer 131b or projections from the second electrode layer 140b toward the second oxygen-deficient tantalum oxide layer 132b were not formed at all.

The initial resistance of each of the above-mentioned elements (elements shown in FIGS. 2A and 2B), i.e. the resistance value between the first electrode layer (120a, 120b) and the second electrode layer (140a, 140b) immediately after the completion of the sample production process including the heating step, was measured. The initial resistance of the sample shown in FIG. 2A (element with Pt projections) was about 10²Ω, whereas the initial resistance of the sample shown in FIG. 2B (element without Pt projections) was about 10⁸Ω. Thus, the initial resistance was lower by six orders of magnitude in the presence of Pt projections.

Here, the first oxygen-deficient tantalum oxide layer (131a, 131b) is provided to induce a resistance change phenomenon of the element shown in FIG. 2A or 2B and simultaneously adjust the variable resistance element to have a high initial resistance, and so has a very important role in achieving stable resistance change operations of the variable resistance element composed of the element shown in FIG. 2A or 2B.

This being so, the presence of projections as shown in FIG. 2A makes it impossible to attain the initial resistance as designed. The film thickness of the first oxygen-deficient tantalum oxide layer 131a substantially decreases in the projection parts, so that the total resistance value is lower than in the case where no element projections are present. Even when projections are formed, the resistance value can be designed while also taking the contribution of the projections into consideration if projection reproducibility is high. In actuality, however, it is difficult to control projection density, size, and the like with high reproducibility. Therefore, the formation of projections causes a decrease in reproducibility of electrical characteristics of the element.

Besides, when a voltage is applied across the first electrode layer 120a and the second electrode layer 140a in the state shown in FIG. 2A, an electric field or a current concentrates at the projections. If the voltage application is repeatedly performed in such a situation, there is a possibility that the first oxygen-deficient tantalum oxide layer 131a and the second oxygen-deficient tantalum oxide layer 132a break near the projections and the first electrode layer 120a and the second electrode layer 140a short out, as a result of which a resistance change fails to occur. Thus, the formation of projections can also cause a decrease in reliability (durability) of the element.

This suggests that the reproducibility of electrical characteristics and the operational reliability of the variable resistance element are expected to be improved if the formation of projections from the electrodes toward the oxygen-deficient tantalum oxide layers can be suppressed.

The following is a projection formation mechanism, as an example. A change in the Pt layer in the heating step in the manufacturing process is one probable cause. For instance, migration of Pt atoms when the Pt layer reaches a high temperature can cause projection formation. A possible reason why the projections develop from the grain boundaries of the Pt layer is that such migration tends to occur along the grain boundaries of the Pt layer.

### (Experiment 2)

The inventors of the present invention then examined whether or not the same problem arises in the case of using hafnium instead of tantalum as the transition metal included in the variable resistance layer.

FIGS. 3A and 3B are each a transmission electron microscope (TEM) photograph showing a cross section of a nonvolatile memory element in which oxygen-deficient hafnium oxide is used in the variable resistance layer. FIG. 3A corresponds to the case where 400° C. is the maximum temperature in the process, and FIG. 33 corresponds to the case where 100° C. is the maximum temperature in the process.

In the element shown in FIG. 3A, an oxygen-deficient hafnium oxide layer 230c of about 30 nm in film thickness and a first electrode layer 220c comprising Pt of about 75 nm in film thickness are stacked in this order on a second electrode layer 240c comprising a W (tungsten) layer of about 150 nm in film thickness. The element shown in FIG. 3A was equally produced using the process technology relating to semiconductor device manufacturing, with the maximum temperature in the heating step in the process being about 400° C.

As is clear from a close study of FIG. 3A, when heated at 400° C., wide projections (circled parts in the photograph, 3 nm or more in size) comprising Pt were formed from the first electrode layer 220c in a downward direction in the photograph (direction toward the oxygen-deficient hafnium oxide layer 230c), that is, from the first electrode layer 220c toward the variable resistance layer,

In the element shown in FIG. 3B, an oxygen-deficient hafnium oxide layer 230d of about 30 nm in film thickness and a first electrode layer 220d comprising a Pt layer of about 75 nm in film thickness are stacked in this order on a second electrode layer 240d comprising a W layer of about 150 nm in film thickness. The manufacturing method of the element shown in FIG. 3B is the same as that of the element shown in FIG. 3A, but the maximum temperature in the heating step in the process is limited to about 100° C. Projections comprising Pt were not formed in this element, as shown in FIG. 3B.

These results suggest that, in the variable resistance element 10 (nonvolatile memory element) including a Pt layer (electrode layer) of a large film thickness and an oxygen-deficient transition metal oxide as its components, Pt projections tend to be formed when exposed to a high temperature of about 400° C., regardless of the type of transition metal.

It can be understood from the above experimental results that the formation of projections is suppressed if the heating step is omitted when forming the variable resistance element 10. In the ordinary semiconductor process, however, the heating step of about several hundred degrees is essential to improve wiring reliability, and therefore it is impractical to set an upper limit of the heating temperature in the manufacturing process to about 100° C.

### (Experiment 3)

As a result of conducting further study based on these findings, the inventors of the present invention have found out that projections can be suppressed by reducing the film thickness of the electrode layer comprising Pt. This is described below.

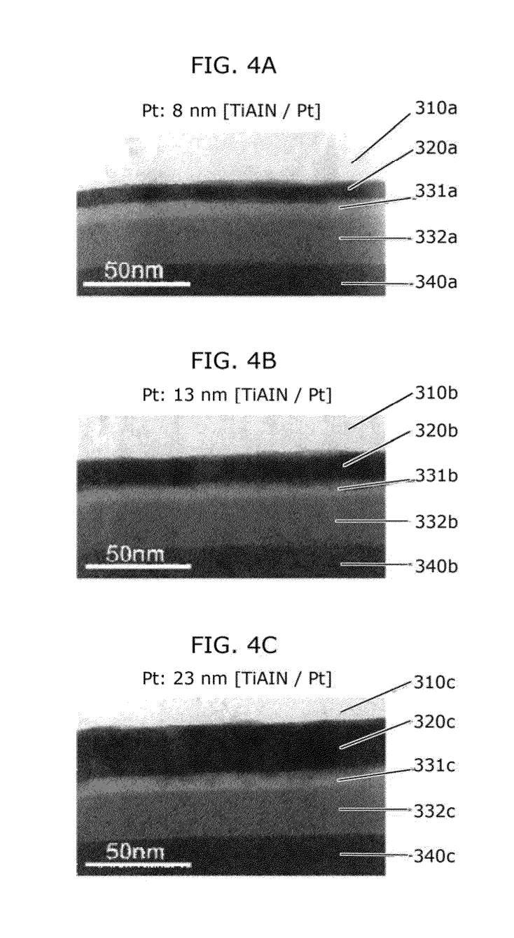

FIGS. 4A to 4C are each a transmission electron microscope (TEM) photograph showing an element cross section in this example. FIG. 4A shows a cross section of an element A, FIG. 4B shows a cross section of an element B, and FIG. 4C shows a cross section of an element C.

A first electrode layer 320a comprising a Pt layer in the element A shown in FIG. 4A is 8 nm in thickness, a first electrode layer 320b comprising a Pt layer in the element B is 13 nm in thickness, and a first electrode layer 320c comprising a Pt layer in the element C is 23 nm in thickness. All of the elements have the same structure except the thickness of the Pt layer. In detail, in the element A shown in FIG. 4A, a second electrode layer 340a, a second oxygen-deficient tantalum oxide layer 332a of about 23 nm in film thickness, a first oxygen-deficient tantalum oxide layer 331a of about 8 nm in film thickness, the first electrode layer 320a comprising a Pt layer of 8 nm, and a conductive layer 310a are stacked in this order. In the element B shown in FIG. 4B, a second electrode layer 340b, a second oxygen-deficient tantalum oxide layer 332b of about 23 nm in film thickness, a first oxygen-deficient tantalum oxide layer 331b of about 8 nm in film thickness, the first electrode layer 320b comprising a Pt layer of 13 nm, and a conductive layer 310b are stacked in this order. In the element C shown in FIG. 4C, a second electrode layer 340c, a second oxygen-deficient tantalum oxide layer 332c of about 23 nm in film thickness, a first oxygen-deficient tantalum oxide layer 331c of about 8 nm in film thickness, the first electrode layer 320c comprising a Pt layer of 23 nm, and a conductive layer 310c are stacked in this order. Hereafter, the first electrode layers 320a, 320b, and 320c each comprising a Pt layer are also collectively referred to as a first electrode layer 320, and the second electrode layers 340a, 340b, and 340c are also collectively referred to as a second electrode layer 340.

A close study of FIGS. 4A to 4C reveals the following. In the element A, no projection was formed from the first electrode layer 320a comprising a Pt layer. In the element B, irregularities of about 2 nm appeared in the first electrode layer 320b comprising a Pt layer, indicating that projections were about to be formed. In the element C, projections reaching near a central part of the first oxygen-deficient tantalum oxide layer 331c were formed in some parts. However, these projections are obscure in shape as compared with the example in FIG. 4A (film thickness of first electrode layer=80 nm).

These results suggest that projections are significantly suppressed by reducing the film thickness of the Pt layer (first electrode layer). The suppression effect decreases as the film thickness of the Pt layer (first electrode layer) increases.

FIG. 5 is a diagram showing results of plotting an initial resistance of each of the elements A, B, and C against the film thickness of the Pt layer in this example. As a comparative example, an initial resistance of a nonvolatile memory element produced by depositing only a Pt layer (80 nm) as the first electrode layer is plotted, too.

The initial resistance mentioned here means a resistance value (resistance value between the first electrode layer 320 and the second electrode layer 340) immediately after element formation. That is, for an element that has undergone the manufacturing process including the heating step, the initial resistance is a resistance value measured in a state where no electrical pulse (high-voltage electrical pulse that causes a change in resistance value) is applied yet. The initial resistance was measured by applying a weak voltage of 50 my across the first electrode layer 320 and the second electrode layer 340 and measuring current flow,

As shown in FIG. 5, the initial resistance of the element A (film thickness of Pt layer=8 nm) was very high about 10⁸Ω, which is approximately equal to the resistance value of the element shown in FIG. 2B described earlier (element produced while limiting the heating step in the process to about 100° C.). However, the initial resistance decreased to 10⁶Ω in the element B (film thickness of Pt layer=13 nm), and to about 800Ω in the element C (film thickness of Pt layer=23 nm). On the other hand, the initial resistance of the element produced as the comparative example (film thickness of Pt layer=80 nm) was about 300Ω. Thus, the initial resistance of the comparative example was about half that of the element C.

These results suggest that the decrease in resistance value with the increase in film thickness of the Pt layer is closely correlated with the formation of projections or irregularities in the Pt layer. When the film thickness of the Pt layer increases, Pt projections (irregularities) develop toward the inside of the first oxygen-deficient tantalum oxide layer, as a result of which the film thickness of the first oxygen-deficient tantalum oxide layer substantially decreases in some parts. The first oxygen-deficient tantalum oxide layer has a higher resistance than the second oxygen-deficient tantalum oxide layer. Accordingly, when Pt projections enter into the first oxygen-deficient tantalum oxide layer, the initial resistance of the element decreases significantly. Conversely, a higher initial resistance of the element indicates a greater effect of suppressing Pt projections.

As can be seen from FIG. 5, there is a tendency that, when the film thickness of the Pt layer exceeds 20 nm, the initial resistance is substantially constant (about several hundred Ω) and the decrease in resistance value is saturated. Hence, it is preferable to set the film thickness of the Pt layer to 20 nm or less, in order to suppress Pt projections and projection-like irregularities.

The following is a projection suppression mechanism in the case of reducing the film thickness of the Pt layer. As mentioned earlier, it is estimated that Pt projections are caused by Pt atoms migrating along grain boundaries present in the Pt layer. If no grain boundary is present, migration is unlikely to occur, se that no projection is formed.

Typically, in the case of depositing a metal or the like on a substrate, when the film thickness is larger, crystal grains (grains, crystalline lumps) grow more and as a result grain boundaries become clearer. When the film thickness is smaller, on the other hand, the grain growth is insufficient and grain boundaries do not appear clearly. This is demonstrated by the fact that clear grain boundaries as seen in FIGS. 2A and 2B are not observed in FIGS. 4A and 4B. Thus, in the case where the Pt layer is very thin (about 8 nm) as in the element A, Pt migration along grain boundaries does not occur and therefore no projection is formed even when exposed to a high temperature of 400° C. As the film thickness of the Pt layer increases as in the elements B and C, however, grain boundaries become clearer and projection-like irregularities are gradually formed.

It is also estimated that, since projections are caused by migration of Pt atoms, projections are less likely to be formed if there are fewer Pt atoms which migrate. That is, the number of Pt atoms is also a probable contributory factor in suppressing projections. Reducing the film thickness of the Pt layer is equivalent to reducing the number of Pt atoms. In the elements A to C, the formation of projections is suppressed because there are fewer Pt atoms which migrate.

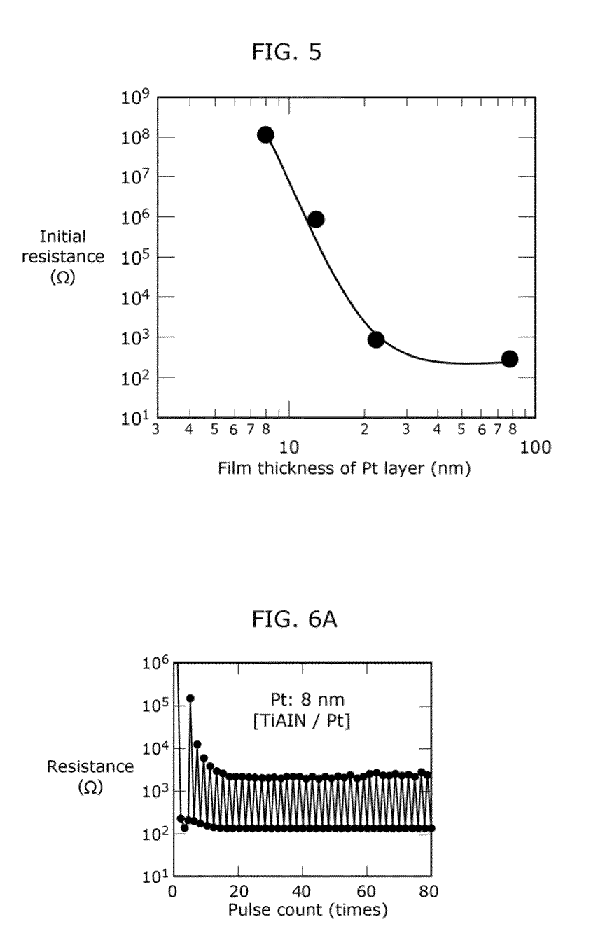

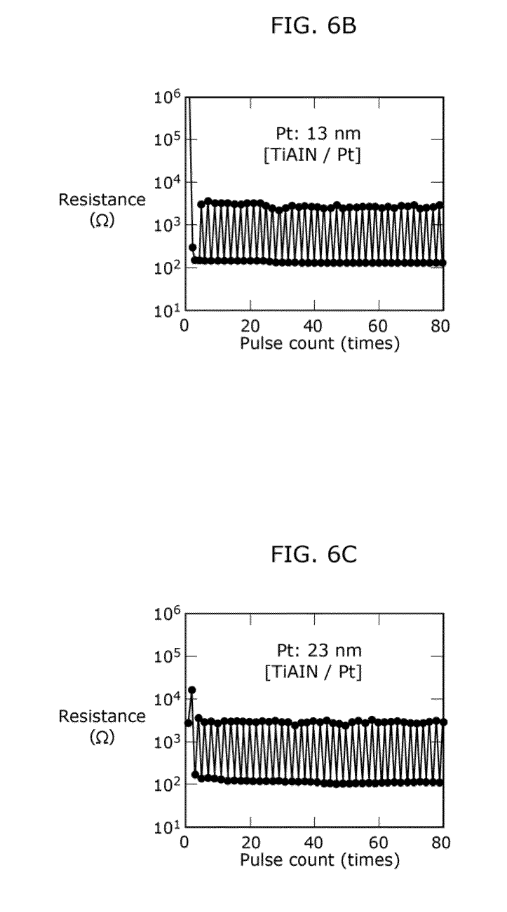

Whether or not the elements A, B, and C perform resistance change operations was examined next. This is described below. FIG. 6A is a diagram showing resistance change operations of the element A in this example, FIG. 6B is a diagram showing resistance change operations of the element B in this example, and FIG. 6C is a diagram showing resistance change operations of the element C in this example.

Here, a voltage polarity is represented by a voltage of the first electrode layer 320 with respect to the second electrode layer 340. In detail, a voltage in the case where a higher voltage is applied to the first electrode layer 320 than the second electrode layer 340 is regarded as a positive voltage, whereas a voltage in the case where a lower voltage is applied to the first electrode layer 320 than the second electrode layer 340 is regarded as a negative voltage. The voltage application was performed using electrical pulses of 100 ns in pulse width. The resistance value was measured by measuring the current when applying a weak voltage of 50 mV across the electrodes (first electrode layer 320 and second electrode layer 340) before the application of each electrical pulse.

In FIG. 6A, voltages of electrical pulses applied to the element A are as follows: first time: −1.5 V; second time: +1.7 V; third time −1.5 V. From the fourth time, +1.7 V and −1.5 V were alternately applied as from the second time. In FIG. 6A, the resistance value (initial resistance value) before the first-time pulse application is not less than 10⁶Ω (not less than a device measurement limit), and the measurement point is outside the graph and so is not shown. In the element A, once the pulse count exceeds ten, the resistance value is stable at about 3000Ω upon application of +1.7 V, and stable at about 100Ω upon application of −1.5 V, as shown in FIG. 6A. Thus, the element A exhibits stable resistance change operations once the pulse count exceeds ten.

In FIG. 6B, voltages of electrical pulses applied to the element B are as follows: first time: −1.5 V; second time: +1.7 V; third time: −1.5 V. From the fourth time, +1.7 V and −1.5 V were alternately applied as from the second time. In FIG. 6B, too, the resistance value (initial resistance value) before the first-time pulse application is not less than 10⁶Ω (not less than the device measurement limit), and the measurement point is outside the graph and so is not shown. In the element B, once the pulse count exceeds four, the resistance value is stable at about 3000Ω upon application of +1.7 V, and stable at about 100Ω upon application of −1.5 V, as shown in FIG. 6B. Thus, the element B exhibits stable resistance change operations once the pulse count exceeds four.

In FIG. 6C, voltages of electrical pulses applied to the element C are as follows: first time: +1.7 V; second time: −1.5 V; third time: +1.7 V. From the fourth time, −1.5 V and +1.7 V were alternately applied as from the second time. In FIG. 6C, the resistance value (initial resistance value) before the first-time pulse application is about 3000Ω. In the element C, once the pulse count exceeds three, the resistance value is stable at about 3000Ω upon application of +1.7 V, and stable at about 100Ω upon application of −1.5 V, as shown in FIG. 6B. Thus, the element C exhibits stable resistance change operations once the pulse count exceeds three.

Though not shown, the element of the comparative example (film thickness of Pt layer=80 nm) was observed to perform substantially same resistance change operations as the elements A to C.

From these results, it can be understood that whether or not the elements A to C perform resistance change operations hardly depends on the film thickness of the Pt layer,

The experimental results and study results described above can lead to the conclusion that, though the film thickness of the Pt layer does not affect resistance change phenomena, there is a preferable range (upper limit) of the film thickness of the Pt layer in terms of reducing variations in initial resistance and improving reliability.

In detail, as shown in FIGS. 4A to 4C, no Pt projection was formed with the Pt layer of 8 nm in film thickness, but projections at Pt interfaces increased with the increase of the film thickness of the Pt layer to 13 nm and 23 nm. However, the projections in FIGS. 4B and 4C are more like irregularities than projections, unlike the projections seen in the element of FIG. 2A (film thickness of Pt layer=80 nm). This indicates that the formation of projections can be suppressed to a certain extent even when the film thickness of the Pt layer is 23 nm as in FIG. 4C. Therefore, it is preferable to set the film thickness of the Pt layer to not more than 23 nm, in order to suppress projections.

As shown in FIG. 5, there is a tendency that, when the film thickness of the Pt layer is not more than 23 nm, the resistance value significantly increases as the film thickness of the Pt layer decreases. There is also a tendency that, when the film thickness of the Pt layer is more than 23 nm, the resistance value no longer decreases but becomes substantially constant even if the film thickness of the Pt layer further increases. Thus, the initial resistance value is closely correlated with the formation of Pt projections in such a manner that larger projections are formed when the resistance value is lower. In other words, the results shown in FIG. 5 can be attributed to the fact that projections develop into the first oxygen-deficient tantalum oxide layer of high electrical resistance and thus the effective film thickness of the first oxygen-deficient tantalum oxide layer decreases. The initial resistance measurement results in FIG. 5 indicate that the projection suppression effect is high in the range where the Pt film thickness is not more than 23 nm and low in the range where the Pt film thickness is more than 23 nm. Therefore, it is further preferable to set the film thickness of the Pt layer to not more than 23 nm.

Thus, the results obtained in terms of instrumental analysis in FIGS. 4A to 4C and the results obtained in terms of electrical characteristics in FIG. 5 are substantially in agreement with each other in that the upper limit of the film thickness of the Pt layer to produce the projection suppression effect is about 23 nm. From the cross section TEM observation results in FIGS. 4A to 4C, it can also be concluded that the film thickness of the Pt layer needs to be not more than 8 nm in order to completely eliminate projection

The following examines whether or not the Pt film thickness has a lower limit.

As mentioned earlier, Pt is a material that has a high standard electrode potential and accordingly facilitates a resistance change of the variable resistance layer in contact with Pt (i.e. facilitates a change in resistance value when an electrical pulse is applied). There is a possibility that this resistance change is induced by movement of oxygen atoms near the interface between the electrode and the oxygen-deficient tantalum oxide layer. Pt is also well known as a material that acts as a catalyst for an oxidation reduction reaction.

Considering all of these factors, it can be assumed that, in the variable resistance element 10 in this embodiment, Pt acts as a catalyst on the oxygen-deficient tantalum oxide layer to promote movement of oxygen atoms, as a result of which a resistance change operation is facilitated. That is, in the variable resistance element 10 in this embodiment, the resistance value increases as a result of oxygen being supplied (oxidation) to the oxide layer near the interface between the Pt layer (first electrode 2) and the oxygen-deficient tantalum oxide layer (first metal oxide layer 31), and decreases as a result of oxygen being lost (reduction) from the oxygen-deficient tantalum oxide layer (first metal oxide layer 31) near the interface. Here, Pt acts to decrease activation energy for causing the oxidation reduction reaction of the oxide layer, i.e. acts as a catalyst.

In view of this, the Pt layer (first electrode 2) needs to cover the entire surface of the oxygen-deficient tantalum oxide layer (first metal oxide layer 31) without any gap. In the case where the Pt layer (first electrode 2) that is not continuous but separated like islands partially covers the oxygen-deficient tantalum oxide layer (first metal oxide layer 31), the area exhibiting the resistance change in the oxygen-deficient tantalum oxide layer varies depending on the size or density of each island-like Pt layer (first electrode 2), causing variations in resistance value.

Hence, the extent to which Pt needs to be deposited to form a film (continuous film) covering the entire surface without any gap was examined using X-ray photoelectron spectroscopy (XPS).

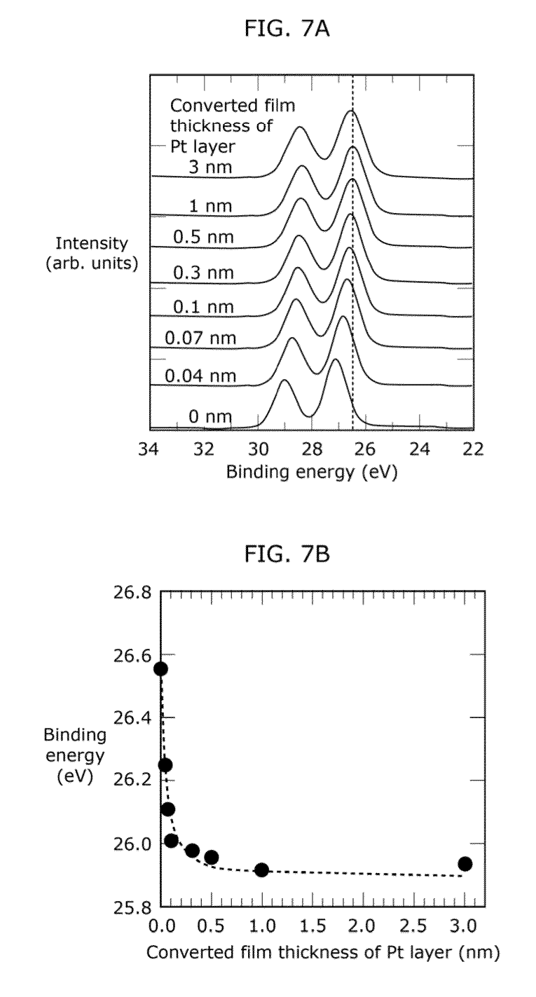

FIG. 7A is a diagram showing relations between a converted film thickness of the Pt layer and binding energy in this example.

A detailed experimental method in FIG. 7A is as follows.

First, an oxygen-deficient tantalum oxide layer was deposited on a substrate, and its surface was naturally oxidized in atmosphere. A Pt layer was then deposited on the oxygen-deficient tantalum oxide layer by sputtering with different film thicknesses, and an XPS spectrum in each film thickness was measured. The film thickness of the Pt layer was adjusted by a sputtering time. Note that the term “converted film thickness” means a virtual film thickness calculated from the sputtering time based on an assumption that the film thickness is proportional to the sputtering time. When the film thickness is large (when a continuous film is formed), the converted film thickness and the actual film thickness match. When the film thickness is small, the film does not have a uniform thickness and is separated like islands. It is difficult to define the film thickness in such a case. The “converted film thickness” in the case where the film thickness is small substantially matches an average film thickness of the Pt layer separated like islands,

FIG. 7A shows how a spectrum of 4f electrons in Ta inner shells changes according to the film thickness of the Pt layer. In FIG. 7A, plotting is made with the horizontal axis being vertically shifted for each converted film thickness, to ease comparison of each spectrum.

As shown in FIG. 7A, a peak of 4f electrons of Ta shifts to the lower energy side as the film thickness of the Pt layer increases. Such shift can be attributed to a change (band bending) in energy band structure caused by depositing Pt on the oxygen-deficient tantalum oxide layer. The shift increases with an increase in proportion in which the surface of the oxygen-deficient tantalum oxide layer is covered with the Pt layer. No further peak shift occurs when the entire surface of the oxygen-deficient tantalum oxide layer is covered with the Pt layer (the Pt layer is a continuous film). When referencing to FIG. 7A while taking this into consideration, it can be understood that the peak shift of 4f electrons of Ta occurs continuously in the case where the converted film thickness of the Pt layer is in a range of 0 nm to 1 nm. This means that the Pt layer is not a continuous film but an island-like discontinuous film when the converted film thickness is less than 1 nm. When the converted film thickness is not less than 1 nm, on the other hand, no peak shift of 4f electrons of Ta occurs, and the Pt layer is a continuous film.

FIG. 7B is a diagram plotting a position of a binding energy value (around 27 eV) of the main peak of each spectrum in FIG. 7A against the film thickness of the Pt layer. As can be seen from FIG. 7B, too, no peak shift occurs when the converted film thickness of the Pt layer is not less than 1 nm.

Thus, the Pt layer on the oxygen-deficient tantalum oxide is a continuous film when its film thickness is not less than 1 nm. Since transition metal oxides have substantially similar characteristics, the Pt layer is a continuous film with the substantially same film thickness even in the case where Pt is deposited on a transition metal oxide other than tantalum oxide.

Therefore, according to this example, the film thickness range of the Pt layer is not less than 1 nm and not more than 23 nm, preferably not less than 1 nm and not more than 23 nm, more preferably not less than 1 nm and not more than 13 nm, still more preferably not less than 1 nm and not more than 10 nm, and most preferably not less than 1 nm and not more than 8 nm. The first electrode 2 comprising the Pt layer thus has the preferable film thickness range.

Besides Pt, palladium (Pd) shows the same characteristics as Pt. Accordingly, the same applies even when Pd is used for the first electrode 2, and so its description is omitted.

In the case of using iridium (Ir) as the material of the first electrode 2, on the other hand, Ir projections were not formed in the interface with the first metal oxide layer even when heated at 400° C. after electrode formation, regardless of the film thickness of Ir. This is probably because, as compared with Pt and Pd, Ir has a low thermal expansion coefficient, a high melting point, and a high Young's modulus, and therefore does not thermally expand much by annealing, resists thermal diffusion due to its high melting point, and is not deformed much by applied stress.

In the experiments in this example, each element (sample) corresponding to the variable resistance element was produced by forming the second tantalum oxide layer (second metal oxide layer 32), the first tantalum oxide layer (first metal oxide layer 31), and the first electrode 2 in this order on the second electrode 4. However, given that Pt migration occurs regardless of the vertical positional relation of the first electrode 2 and the second electrode 4 as shown by the results in FIGS. 2A and 2B, the same effect of suppressing migration in the first electrode 2 can be attained even in the case where the first tantalum oxide layer, the second tantalum oxide layer, and the second electrode 4 are formed in this order on the first electrode 2,

### [Method of Manufacturing Variable Resistance Element]

The following describes a method of manufacturing the variable resistance element 10 having the above structure.

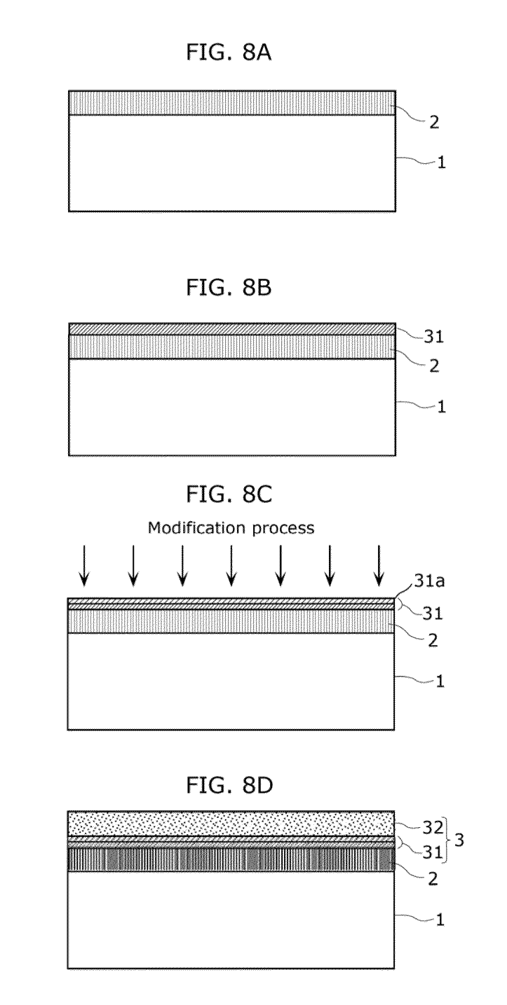

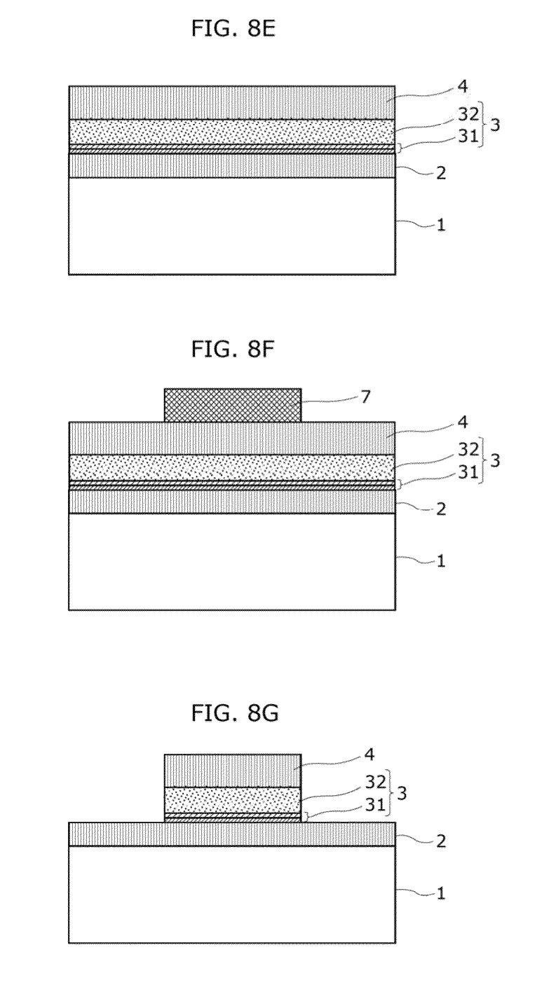

FIGS. 8A to 8G are diagrams for describing the method of manufacturing the variable resistance element 10 according to the present invention.

First, the first electrode 2 (Ir of 80 nm in film thickness here) is formed in the above-mentioned preferable film thickness range, on the substrate 1 by sputtering (FIG. 8A),

Next, the first tantalum oxide layer (first metal oxide layer 31) is formed on the first electrode 2 by RF sputtering in argon gas, using a tantalum oxide (e.g. Ta₂O₅) target having a high oxygen content atomic percentage (FIG. 8B). Film formation conditions used here are a film formation temperature of 25° C.; power of 1000 W; a film formation pressure of 0.05 Pa; and a gas flow rate of Ar=50 sccm.

Next, the modification step of forming the modified layer by modifying the surface part (31a in FIG. 8C) of the formed first tantalum oxide layer is performed (FIG. 8C). This modification step is conducted in such a manner that, in a state where mixed gas of inert gas and oxygen gas flows and a shutter is closed (so that tantalum oxide deposition by sputtering is not performed) in a DC sputtering apparatus for forming the second tantalum oxide layer (second metal oxide layer 32) in the next step, the surface (surface part 31a) of the first tantalum oxide layer is exposed to mixed gas plasma of inert gas and oxygen gas for at least a predetermined time. In detail, in the DC sputtering apparatus, the surface of the formed first tantalum oxide layer is exposed to mixed gas plasma of inert gas and oxygen gas for at least five seconds with: no substrate heating; power of 1000 W; a pressure of 0.05 Pa; and a gas flow rate of Ar/O₂=20/23 sccm.

Though this modification step uses (shares) a step of stabilizing discharge when sputtering a tantalum target before the formation of the second tantalum oxide layer in the next step starts, the modification step may instead use an oxidation step (in detail, plasma oxidation step) conducted in another apparatus. This will be described in detail later.

Next, the shutter is opened, and the tantalum target is sputtered in argon gas and oxygen gas under the same conditions that are: no substrate heating; power of 1000 W; a film formation pressure of 0.05 Pa; and a gas flow rate of Ar/O₂=20/23 sccm (reactive sputtering). As a result, the second tantalum oxide layer is formed on the first tantalum oxide layer (FIG. 80). Here, the first tantalum oxide layer has a higher oxygen content atomic percentage than the second tantalum oxide layer.

The oxygen content atomic percentage of the second tantalum oxide layer can be easily adjusted by changing the flow rate of oxygen gas to argon gas. Moreover, the substrate temperature can be set to an ambient temperature with no particular heating.

Thus, the first tantalum oxide layer (high resistance layer) having the modified layer and the second tantalum oxide layer (low resistance layer) are stacked to form the metal oxide layer 3.

Next, the second electrode 4 of 50 nm in thickness is formed on the formed metal oxide layer 3 by sputtering (FIG. 8E).

Next, a pattern 7 is formed on the second electrode 4 by a photoresist in a photoresist step (FIG. 8F), and dry etching is performed so as to leave a desired region (variable resistance element region).

The variable resistance element 10 is manufactured in this way.

The size and shape of the variable resistance element region, i.e. the size and shape of the first electrode 2, the second electrode 4, and the metal oxide layer 3, can be adjusted by masking and lithography. In this embodiment, the size of the second electrode 4 and the metal oxide layer 3 is 0.5 μm×0.5 μm (an area of 0.25 μm²), and the size of the contact part of the first electrode 2 and the metal oxide layer 3 is also 0.5 μm×0.5 μm (an area of 0.25 μm²).

Moreover, in this embodiment, the composition of the first tantalum oxide layer is TaOₓ (x=2.47), and the composition of the second tantalum oxide layer is TaO_{y} (y=1.54).

Note that the values of x and y are not limited to x=2.47 and y=1.54, so long as x is not less than 2.1 (2.1≦x) and y is not less than 0.8 and not more than 1.9 (0.8≦y≦1.9) as mentioned earlier. With this range, a stable resistance change can be realized as in the resistance change characteristics in this embodiment.

### (Experiment 4)

The modification of the surface part 31a of the first tantalum oxide layer (first metal oxide layer 31) by the above-mentioned modification step is described using experimental results below.

First, a sample of a film formed under the same conditions as the above-mentioned first tantalum oxide layer was subjected to plasma oxidation of the same conditions as the film formation conditions of the second tantalum oxide layer (second metal oxide layer 32) except that the shutter is closed, and a film quality change was analyzed.

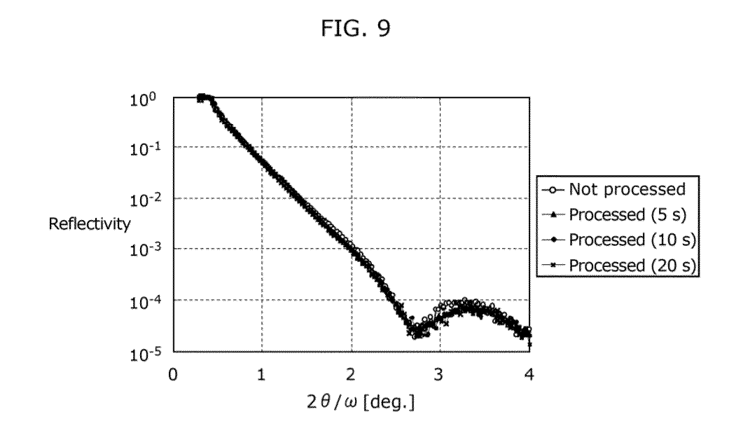

Film structure analysis was conducted first by a grazing incidence X-ray reflective (GIXR) technique. This is a method of making X-rays incident on a sample surface at a very shallow angle and measuring an intensity of reflected X-rays (measurement apparatus: ATX-E by Rigaku Corporation). Fitting was performed for the spectrum by assuming an appropriate structural model, and a film thickness, a density (refractive index), and surface roughness were evaluated. Here, fitting parameters are a refractive index, a film thickness, and surface roughness. FIG. 9 shows results of measuring an X-ray reflectivity profile for each sample. Changes of X-ray reflectivity on the sample surface were measured while varying an angle θ of the X-rays with the sample surface and a detector angle (angle θ of the detector with the sample surface) in conjunction with each other. An angle from an extension line of the incident X-rays to the detector is 2θ. In FIG. 9, the horizontal axis represents 2θω (twice the X-ray incident angle θ is expressed in degrees), and the vertical axis represents X-ray reflectivity.

In FIG. 9, the X-ray reflectivity profiles of a sample a (triangle mark in FIG. 9) with a plasma oxidation condition of 5 seconds, a sample b (lozenge mark in FIG. 9) with a plasma oxidation condition of 10 seconds, a sample c (cross mark in FIG. 9) with a plasma oxidation condition of 20 seconds, and a sample d (circle mark in FIG. 9) without plasma oxidation are compared with each other.

As shown in FIG. 9, the profiles where 2θ/ω is near 3 degrees are different depending on whether or not plasma oxidation is performed. Meanwhile, there is almost no difference in profile depending on the processing time.

Table 1 shows results of calculating a δ value, a film thickness, and surface roughness by least square fitting for the measurement results shown in FIG. 9. X-ray reflectivity data processing software by Rigaku Corporation was used for fitting. The δ value is a value proportional to density, and is expressed as δ=1−n where n is a refractive index of a material for X-rays. In Table 1, “not processed” corresponds to the sample d, “processed (5 s)” corresponds to the sample a, “processed (10 s)” corresponds to the sample b, and “processed (20 s)” corresponds to the sample c.

TABLE 1

| | δ value (×10⁻⁶) | film thickness [nm] | roughness [nm] |
|---|---|---|---|
| not processed | 19.63 | 3.55 | 0.49 |
| processed (5 s) | 19.08 | 3.58 | 0.54 |
| processed (10 s) | 19.09 | 3.58 | 0.54 |
| processed (20 s) | 18.88 | 3.58 | 0.54 |

As shown in Table 1, the film thickness slightly increased from 3.55 nm to 3.58 nm by plasma oxidation. In addition, the surface roughness increased from 0.49 nm to 0.54 nm by 0.05 nm by plasma oxidation. The δ value (density) showed a tendency of being smaller when the processing time is longer.

In the case of tantalum oxide, a higher oxygen composition contributes to a smaller δ value (density), and also there is a slight increase in film thickness. This indicates that the oxygen concentration of the first tantalum oxide layer increases by plasma oxidation.

Next, a Ta4F spectrum and an O1s spectrum were measured by X-ray photoelectron spectroscopy, in order to examine the oxygen composition of each of the above samples (samples a to d).

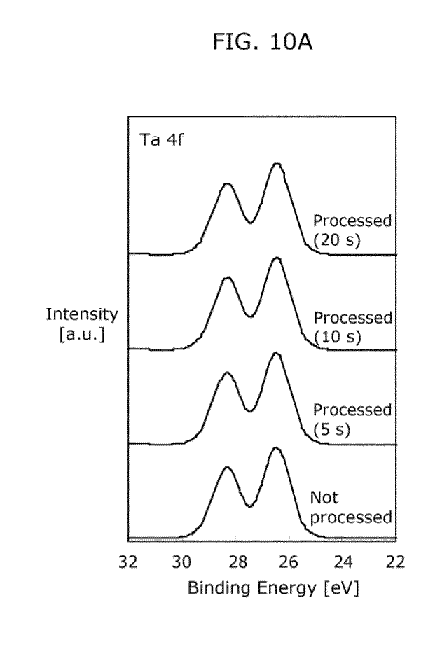

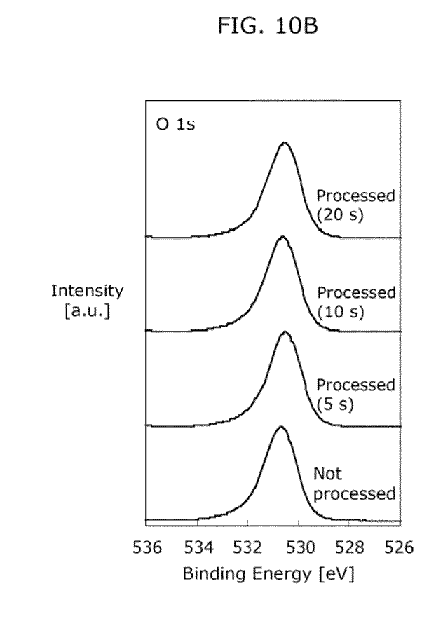

FIGS. 10A and 10B are diagrams showing measurement results of the first tantalum oxide layer in the above-mentioned modification step by X-ray photoelectron spectroscopy (XPS). FIG. 10A shows Ta4f spectrum measurement results, and FIG. 10B shows O1s spectrum measurement results.

From integrated intensities of the Ta4f peak shown in FIG. 10A and the O1s peak shown in FIG. 10B, whether or not an approximate composition ratio of tantalum and oxygen relatively changes can be recognized. Note that an absolute value of the composition ratio is not accurate.

Table 2 shows results of calculating the composition ratio of each sample and its increase rate.

TABLE 2

| | | Composition ratio |
|---|---|---|
| | O/Ta composition ratio | increase rate (%) |
| not processed | 3.08 | — |
| processed (5 s) | 3.09 | 0.5 |
| processed (10 s) | 3.10 | 0.8 |
| processed (20 s) | 3.14 | 2.1 |

As shown in Table 2, an increase by 2.1% was observed at the maximum, showing a tendency that the oxygen composition increases when the processing time is longer, as compared with when the process is not performed.

These results are in agreement with the tendency of the 5 value in X-ray reflectivity measurement. This demonstrates that the oxygen composition of the first tantalum oxide layer increases by plasma oxidation. To be more precise, the oxygen composition of the surface part 31a of the first tantalum oxide layer increases,

By forming the metal oxide layer 3 in this way, the film quality of the first tantalum oxide layer can be controlled so that more oxygen is present.

### (Experiment 5)

In Experiment 5, the electrical characteristics of the variable resistance element 10 formed as described above were measured.

First, three types of samples (hereafter referred to as samples 1 to 3) that each have the metal oxide layer 3 of 50 nm in total thickness and that differ in thickness of the first tantalum oxide layer (first metal oxide layer 31) and the second tantalum oxide layer (second metal oxide layer 32) were prepared as samples of the variable resistance element 10.

In detail, in the sample 1, the first tantalum oxide layer is 3 nm in thickness, and the second tantalum oxide layer is 47 nm in thickness. In the sample 2, the first tantalum oxide layer is 4 nm in thickness, and the second tantalum oxide layer is 46 nm in thickness. In the sample 3, the first tantalum oxide layer is 5 nm in thickness, and the second tantalum oxide layer is 45 nm in thickness.

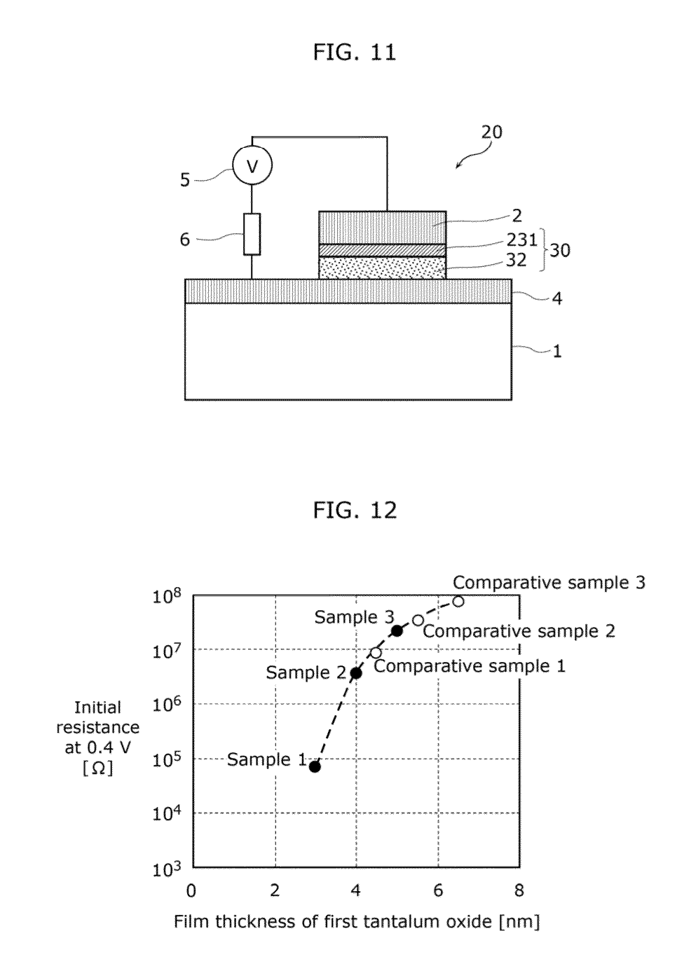

Three types of samples (hereafter referred to as comparative samples 1 to 3) of a variable resistance element 20 whose film structure is upside down as shown in FIG. 11 were also prepared as comparative examples of the samples 1 to 3. FIG. 11 is a schematic diagram showing a structure of a variable resistance element as a comparative sample in this example. In FIG. 11, the same components as those in FIG. 1 are given the same reference signs,

The comparative sample has the upside-down structure for the following reason. In the structure of the variable resistance element 10, the surface of the first tantalum oxide layer is exposed to mixed gas plasma of Ar and oxygen when forming the second tantalum oxide layer. Hence, the comparative sample that is completely free from such an effect is provided.

A method of manufacturing the variable resistance element 20 as the comparative sample is described below.

First, the second electrode 4 (TaN film here) of 50 nm in thickness is formed by sputtering.

Next, the second tantalum oxide layer is formed on the second electrode 4 by reactive DC sputtering of a tantalum target in argon gas and oxygen gas. Film formation conditions used here are: no substrate heating; power of 1000 W; a film formation pressure of 0.05 Pa; and a gas flow rate of Ar/O₂=20/23 sccm. These film formation conditions are exactly the same as those in the step in FIG. 8B.

Next, the first tantalum oxide layer is formed on the second tantalum oxide layer by RF sputtering in argon gas, using a tantalum oxide (e.g. Ta₂O₅) target having a high oxygen content atomic percentage. Film formation conditions used here are: no substrate heating; power of 1000 W; a film formation pressure of 0.05 Pa; and a gas flow rate of Ar=50 sccm. These film formation conditions are exactly the same as those in the step in FIG. 5D.

The second tantalum oxide layer and the first tantalum oxide layer constitute a metal oxide layer 30.

Next, the first electrode 2 (Ir film here) of 50 nm in thickness is formed on the formed metal oxide layer 30 by sputtering.

Lastly, the pattern 7 is formed on the first electrode 2 by a photoresist in a photoresist step, and dry etching is performed so as to leave a desired region (element region). The variable resistance element 20 can be manufactured in this way.

In the comparative samples, i.e. the comparative samples 1 to 3, the size of the second electrode 4 and the metal oxide layer 30 is 0.5 μm×0.5 μm (an area of 0.25 μm²), and the size of the contact part of the first electrode 2 and the metal oxide layer 30 is also 0.5 μm×0.5 μm (an area of 0.25 μm²), as in the samples 1 to 3.

Moreover, in the comparative samples, i.e. the comparative samples 1 to 3, the composition of the first tantalum oxide layer is TaOₓ (x=2.47), and the composition of the second tantalum oxide layer is TaO_{y}, (y=1.54), as in the samples 1 to 3. The comparative samples 1 to 3 each have the metal oxide layer 30 of 50 nm in total thickness, and differ in thickness of the first tantalum oxide layer and the second tantalum oxide layer. In detail, in the comparative sample 1, the first tantalum oxide layer is 4.5 nm in thickness, and the second tantalum oxide layer is 45.5 nm in thickness. In the comparative sample 2, the first tantalum oxide layer is 5.5 nm in thickness, and the second tantalum oxide layer is 44.5 nm in thickness. In the comparative sample 3, the first tantalum oxide layer is 6.5 nm in thickness, and the second tantalum oxide layer is 43.5 nm in thickness.

The comparative samples (comparative samples 1 to 3) have the film structure that involves no modification process of the first tantalum oxide layer. That is, the comparative samples 1 to 3 have the film structure including the first tantalum oxide layer which is unmodified.

The following describes comparison in electrical characteristics between the samples 1 to 3 and the comparative samples 1 to 3 produced as described above.

Definitions of terms used below are described first.

A state in which the metal oxide layer 3 (or the metal oxide layer 30) has a predetermined high resistance value (e.g. several 10 kΩ) is referred to as a high resistance state, and a state in which the metal oxide layer 3 (or the metal oxide layer 30) has a predetermined low resistance value (e.g. several kΩ) is referred to as a low resistance state.

In the variable resistance element 10 shown in FIG. 1, as a result of applying a voltage pulse (referred to as “writing voltage pulse”) across the first electrode 2 and the second electrode 4 using a power source 5 where the voltage pulse causes the first electrode 2 to be negative relative to the second electrode 4, the metal oxide layer 3 decreases in resistance value and changes from the high resistance state to the low resistance state. This is called a writing process.

In the variable resistance element 10 shown in FIG. 1, as a result of applying a voltage pulse (referred to as “erasing voltage pulse”) across the first electrode 2 and the second electrode 4 using the power source 5 where the voltage pulse causes the first electrode 2 to be positive relative to the second electrode 4, the metal oxide layer 3 increases in resistance value and changes from the low resistance state to the high resistance state. This is called an erasing process.

Note that, in the variable resistance element 10 shown in FIG. 1, even when a negative voltage pulse of the same polarity as the writing voltage pulse is applied across the first electrode 2 and the second electrode 4 in the case where the metal oxide layer 3 is in the low resistance state, the metal oxide layer 3 remains in the low resistance state. Likewise, even when a positive voltage pulse of the same polarity as the erasing voltage pulse is applied across the first electrode 2 and the second electrode 4 in the case where the metal oxide layer 3 is in the high resistance state, the metal oxide layer 3 remains in the high resistance state. However, in the case where the resistance value of the metal oxide layer 3 is an initial resistance value (which is a resistance value when no voltage other than a reading voltage has been applied after manufacture of the variable resistance element 10, is normally a higher value (e.g. 20 MΩ) than the resistance value in the above-mentioned high resistance state, and is a resistance value in a state where no resistance change occurs even when the writing voltage pulse or the erasing voltage pulse is applied), a process of applying a pulse of a higher-amplitude voltage or a larger pulse width than the normal writing voltage pulse or erasing voltage pulse across the electrodes needs to be performed to initiate a change in resistance state (a change from the high resistance state to the low resistance state and a change from the low resistance state to the high resistance state). This process is called initial breakdown.

The terms defined above equally apply to the variable resistance element 20 shown in FIG. 11, and so theft detailed description is omitted.

### [Initial Resistance of Variable Resistance Element]

The following examines results of measuring the initial resistance value as the characteristics of the samples 1 to 3 and the comparative samples 1 to 3.

FIG. 12 is a diagram plotting the initial resistance value against the film thickness of the first tantalum oxide layer. The initial resistance of each of the samples 1 to 3 (each variable resistance element) was measured by applying a weak voltage of 0.4 V lower than a threshold voltage (e.g. about 1 V) across the first electrode 2 and the second electrode 4 in the sample and measuring current flow. The initial resistance value of each of the comparative samples 1 to 3 was measured in the same manner.

As shown in FIG. 12, the initial resistance value is higher when the first tantalum oxide layer (first metal oxide layer 31 or first metal oxide layer 231) has a larger film thickness. Thus, the dependence characteristics of the initial resistance on the film thickness are substantially in agreement between the samples 1 to 3 and the comparative samples 1 to 3 (one-to-one relations), and do not differ depending on the difference in film structure.

The first tantalum oxide layer comprises tantalum oxide having a high oxygen content atomic percentage close to Ta₂O₅ and behaves like a semiconductor, so that its resistance is determined by a Schottky junction with the first electrode 2. That is, an interface resistance between the first electrode 2 and the first tantalum oxide layer is dominant in the initial resistance of the variable resistance element 10 or 20.

Since the samples 1 to 3 and the comparative samples 1 to 3 are on the same curved line regarding the initial resistance value, the interface between the first tantalum oxide layer (first metal oxide layer 31) and the first electrode 2 and the interface between the first tantalum oxide layer (first metal oxide layer 231) and the first electrode 2 are equal to each other.

### [Initial Breakdown Characteristics of Variable Resistance Element]

The following examines initial breakdown characteristics as the characteristics of the samples 1 to 3 and the comparative samples 1 to 3.

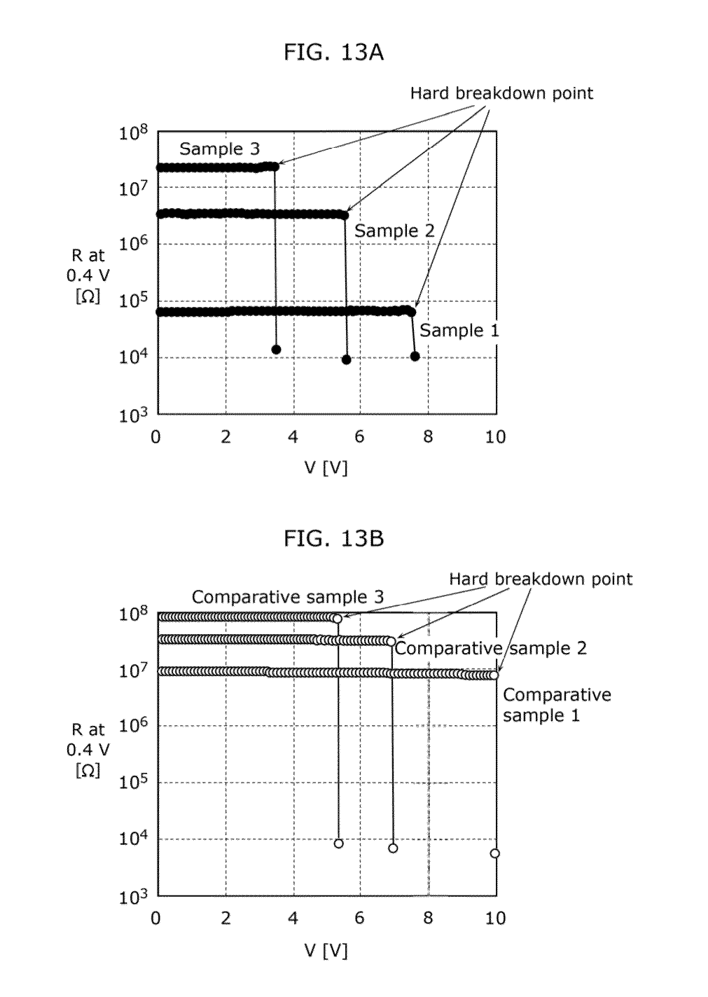

FIG. 13A is a diagram showing a change in resistance value in the variable resistance element 10. FIG. 13B is a diagram showing a change in resistance value in the variable resistance element 20. In detail, FIG. 13A shows a change in resistance value in the case where a voltage pulse that causes the first electrode 2 to be relatively negative is applied across the first electrode 2 and the second electrode 4 of the variable resistance element 10, i.e. the samples 1 to 3, while gradually increasing the voltage pulse from 0.1 V in steps of 0.1 V. Likewise, FIG. 13B shows a change in resistance value in the case where a voltage pulse that causes the first electrode 2 to be relatively negative is applied across the first electrode 2 and the second electrode 4 of the variable resistance element 20, i.e. the comparative samples 1 to 3, while gradually increasing the voltage pulse from 0.1 V in steps of 0.1 V. Assuming that the current steering element (on resistance: 5 kΩ) is connected in series with the variable resistance element 10, the results in the case where a fixed resistor of 5 kΩ is connected as the load resistor 6 are shown here.

As shown in FIGS. 13A and 13B, until the amplitude of the voltage pulse reaches a predetermined threshold voltage (first voltage) from 0.1 V, the resistance value of the variable resistance element (samples 1 to 3 and comparative samples 1 to 3) hardly changes from the initial state. Once the first voltage (depending on the type and film thickness of the metal oxide layer in the variable resistance element, the resistance value, the electrode material, and the like) is exceeded, the resistance value starts to decrease slightly. This phenomenon is called soft breakdown, and the first voltage is called a soft breakdown voltage. The current flowing in the variable resistance element (samples 1 to 3 and comparative samples 1 to 3) to which the soft breakdown voltage is applied is called a soft breakdown current.

When soft breakdown starts, the resistance of the variable resistance element (samples 1 to 3 and comparative samples 1 to 3) decreases and so the voltage distributed to the series-connected load resistor 6 (load resistance value of 5 k) increases, making it difficult to exert a voltage on the variable resistance element. This leads to a phenomenon that, even when the voltage applied across the variable resistance element and the load resistor 6 connected in series is increased, the voltage on the variable resistance element (samples 1 to 3 and comparative samples 1 to 3) hardly changes, and only the current increases.

When the applied voltage is further increased, the resistance value sharply decreases at a second voltage. This phenomenon is called hard breakdown, and the second voltage is called a hard breakdown voltage. The current flowing in the variable resistance element (samples 1 to 3 and comparative samples 1 to 3) to which the hard breakdown voltage is applied is called a hard breakdown current.

The phenomenon of dielectric breakdown as mentioned above can also be seen in a SiO₂ thin film which is a gate oxide film of a semiconductor, for example in the case where the current is steered by a series resistance load. That is, soft breakdown occurs first, and then hard breakdown is reached when a high stress voltage is applied. This is called progressive breakdown and reported, for example, in V. L. Lo etc., IEEE IRDS pp. 602, 2005 (Non Patent Literature).

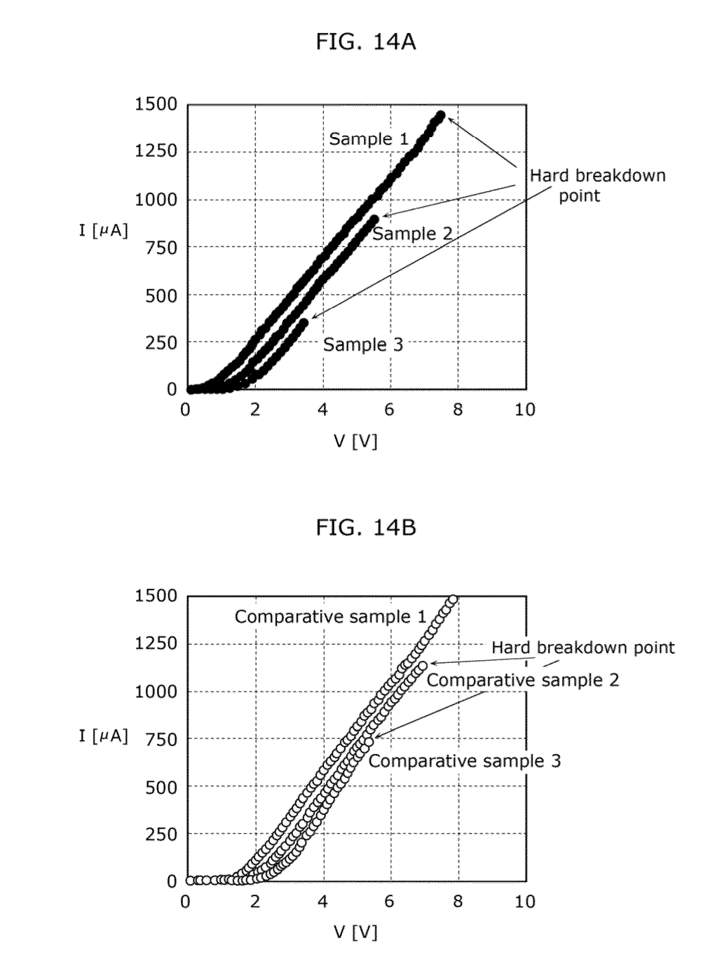

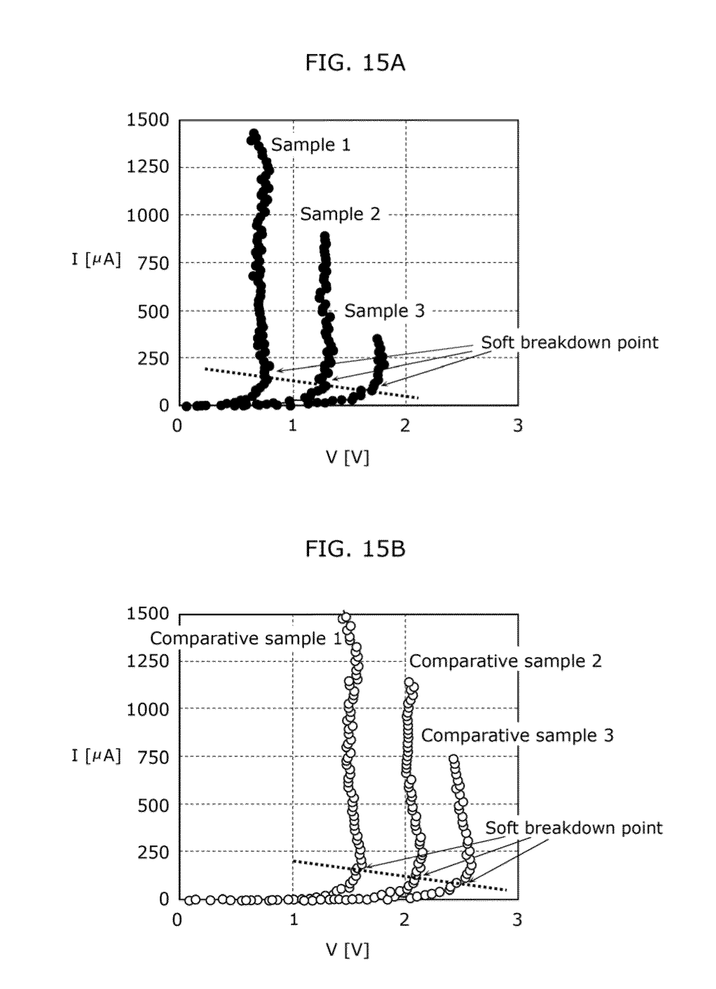

FIG. 14A is a diagram showing current-voltage characteristics of the variable resistance element 10 (samples 1 to 3) until hard breakdown is reached. FIG. 14B is a diagram showing current-voltage characteristics of the variable resistance element 20 (comparative samples 1 to 3) until hard breakdown is reached. The horizontal axis represents a voltage applied to the whole of the variable resistance element and the load resistor. FIG. 15A is a diagram showing current-voltage characteristics of the variable resistance element 10 (samples 1 to 3) until hard breakdown is reached. FIG. 15B is a diagram showing current-voltage characteristics of the variable resistance element 20 (comparative samples 1 to 3) until hard breakdown is reached. The horizontal axis represents a voltage on only the variable resistance element, by subtracting a voltage (5 kΩ×current) on the load resistor of 5 kΩ from the applied voltage. As can be seen from FIGS. 15A and 15B, there is a phenomenon that the voltage on the variable resistance element (samples 1 to 3 and comparative samples 1 to 3) hardly changes and only the current increases even when the voltage applied across the variable resistance element and the load resistor 6 connected in series is increased. A point at which only the current starts to increase while the voltage applied to the variable resistance element is constant is called a soft breakdown point. The voltage applied to the variable resistance element at the soft breakdown point is the soft breakdown voltage, and the current flowing at the time is the soft breakdown current.

The hard breakdown voltage and the hard breakdown current of the variable resistance element 10 (samples 1 to 3) can be read from FIGS. 13A and 14A. Likewise, the hard breakdown voltage and the hard breakdown current of the variable resistance element 20 (comparative samples 1 to 3) can be read from FIGS. 13B and 14B. The soft breakdown voltage and the soft breakdown current of the variable resistance element 10 (samples 1 to 3) can be read from FIG. 15A. Likewise, the soft breakdown voltage and the soft breakdown current of the variable resistance element 20 (comparative samples 1 to 3) can be read from FIG. 15B.

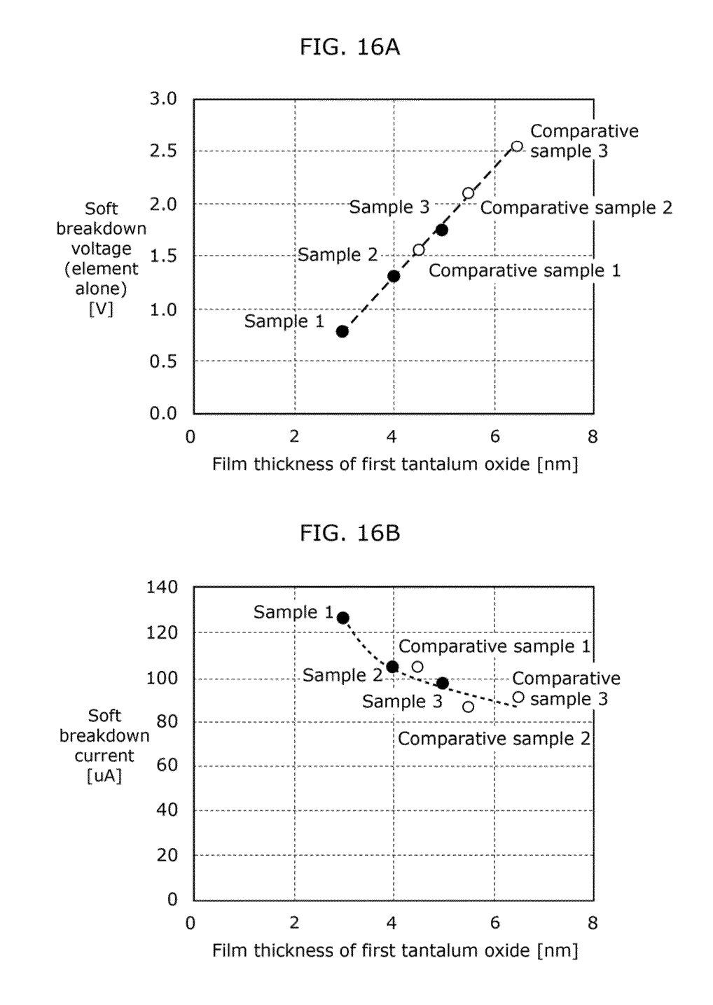

FIGS. 16A and 16B are diagrams plotting the soft breakdown voltage and the soft breakdown current of each variable resistance element against the film thickness of the first tantalum oxide layer (31, 213).

FIG. 16A is a diagram showing relations of the soft breakdown voltage of each of the variables resistance elements 10 and 20 (samples 1 to 3 and comparative samples 1 to 3) with the film thickness of the first tantalum oxide layer (first metal oxide layer 31, 231). FIG. 16B is a diagram showing relations of the soft breakdown current of each of the variables resistance elements 10 and 20 (samples 1 to 3 and comparative samples 1 to 3) with the film thickness of the first tantalum oxide layer (first metal oxide layer 31, 231).

It can be understood from FIGS. 16A and 166 that the relations of the soft breakdown voltage or the soft breakdown current with the film thickness of the first tantalum oxide layer are on the same straight line or curved line, i.e. one-to-one relations. That is, there is no significant difference in soft breakdown point characteristics between the variable resistance element 10 (samples 1 to 3) and the variable resistance element 20 (samples 1 to 3 and comparative samples 1 to 3).

The soft breakdown point can also be regarded as a point at which the initial resistance starts to change slightly, that is, a point at which the state of the first tantalum oxide layer (31, 213) in the interface between the first tantalum oxide layer (31, 213) and the first electrode 2 starts to change.

Accordingly, in the initial state, the state of the interface between the first tantalum oxide layer (31, 213) and the first electrode 2 is substantially the same in the variable resistance element 10 (samples 1 to 3) and the variable resistance element 20 (comparative samples 1 to 3),

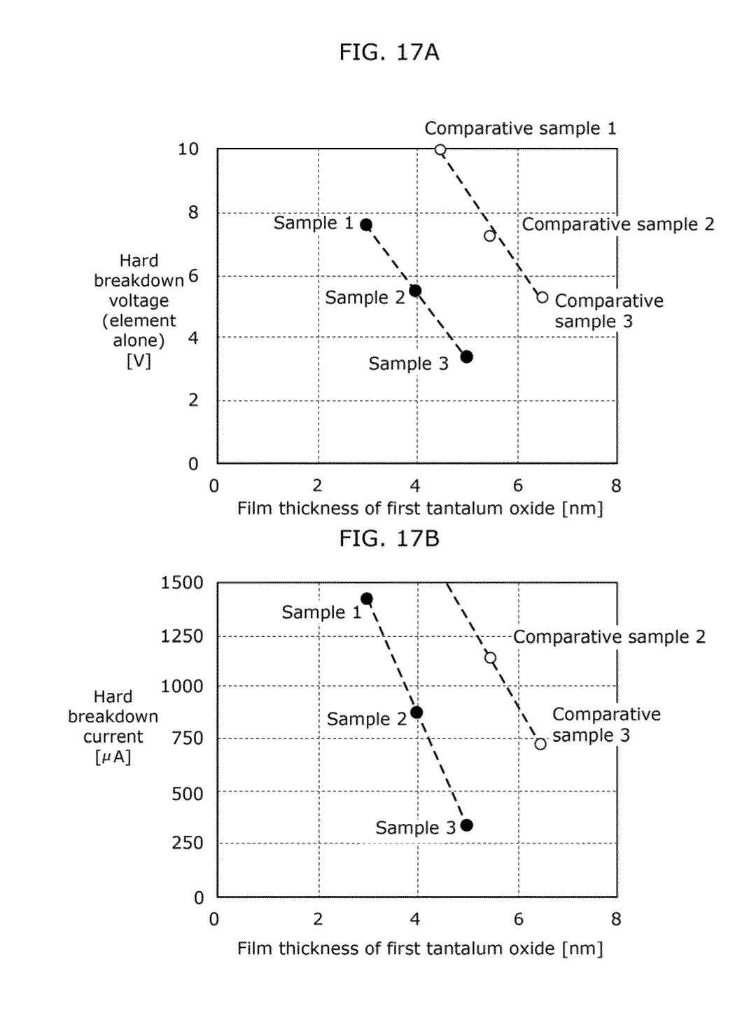

FIGS. 17A and 17B are diagrams plotting the hard breakdown voltage and the hard breakdown current of each variable resistance element against the film thickness of the first tantalum oxide layer (31, 213).

FIG. 17A is a diagram showing relations of the hard breakdown voltage of each of the variables resistance elements 10 and 20 (samples 1 to 3 and comparative samples 1 to 3) with the film thickness of the first tantalum oxide layer (first metal oxide layer 31, 231). FIG. 17B is a diagram showing relations of the hard breakdown current of each of the variables resistance elements 10 and 20 (samples 1 to 3 and comparative samples 1 to 3) with the film thickness of the first tantalum oxide layer (first metal oxide layer 31, 231).

As shown in FIGS. 16A, 16B, 17A, and 17B, in the variable resistance element 10 (samples 1 to 3) and the variable resistance element 20 (comparative samples 1 to 3), there is no significant difference in dependency on the film thickness of the first tantalum oxide layer (31, 213) regarding the soft breakdown point, but the film thickness dependency significantly differs regarding hard breakdown.

In detail, when compared using the same film thickness of the first tantalum oxide layer (31, 213), the variable resistance element 10 has a small hard breakdown voltage at most ½ that of the variable resistance element 20, and a small hard breakdown current at most about ¼ that of the variable resistance element 20. For example, in the case where the film thickness of the first tantalum oxide (31, 213) is 5 nm, the sample 3 has a hard breakdown voltage of 3.4 V and a hard breakdown current of 345 μA, while the comparative sample 1 has a hard breakdown voltage of 8.6 V and a hard breakdown current of 1.4 mA.

That is, in the initial state (i.e. until the start of soft breakdown), the state of the interface between the first tantalum oxide layer (first metal oxide layer 31, 231) and the first electrode 2 is the same. Once soft breakdown starts to occur, however, the effects of not only the state of the interface between the first tantalum oxide layer and the first electrode 2 but also the film quality of the first tantalum oxide layer and the state of the interface between the first tantalum oxide layer and the second tantalum oxide layer (second metal oxide layer 32) emerge. In the variable resistance element 10 (samples 1 to 3), after the first tantalum oxide layer (first metal oxide layer 31) is formed, plasma oxidation is performed to modify the first tantalum oxide layer before forming the second tantalum oxide layer (second metal oxide layer 32).

On the other hand, in the variable resistance element 20 (comparative samples 1 to 3), after the second tantalum oxide layer (second metal oxide layer 32) is formed, the first tantalum oxide layer (first metal oxide layer 231) is formed without the modification process (plasma oxidation) of the first tantalum oxide layer. Its interface is therefore expected to be in a state of being higher in oxygen deficiency than the first tantalum oxide layer (first metal oxide layer 31) of the variable resistance element 10. Hence, after soft breakdown, the current flows comparatively easily (low resistance) due to oxygen deficiency, which causes a relative increase in proportion of the voltage on the load resistor and makes it difficult to exert the voltage on the variable resistance element 20, so that hard breakdown is not easily reached. This leads to increases in hard breakdown voltage and current ensue.

Moreover, the oxygen concentration distribution of the second tantalum oxide layer near the interface between the modified first tantalum oxide layer (first metal oxide layer 31) and the second tantalum oxide layer (second metal oxide layer 32) is not affected by the modification step, and also the oxygen concentration of the first tantalum oxide layer near the interface between the first tantalum oxide layer and the second tantalum oxide layer is higher than the oxygen concentration near the interface between the first electrode 2 and the first tantalum oxide layer.

These results demonstrate that the voltage and the current upon initial breakdown can be reduced by performing such a modification process of the first tantalum oxide layer that reduces the oxygen deficiency of the first tantalum oxide layer near the interface between the first tantalum oxide layer (first metal oxide layer 31) and the second tantalum oxide layer (second metal oxide layer 32) without affecting the oxygen concentration distribution of the second tantalum oxide layer near the interface between the first tantalum oxide layer and the second tantalum oxide layer, as in the variable resistance element 10 in this embodiment.

### [Resistance Change Operation]

Resistance change operations after initial breakdown are described below, using the sample 3 as an example of the variable resistance element 10 and the comparative sample 2 as an example of the variable resistance element 20. The sample 3 and the comparative sample 2 have substantially the same film thickness of the first tantalum oxide layer, i.e. about 5 nm.

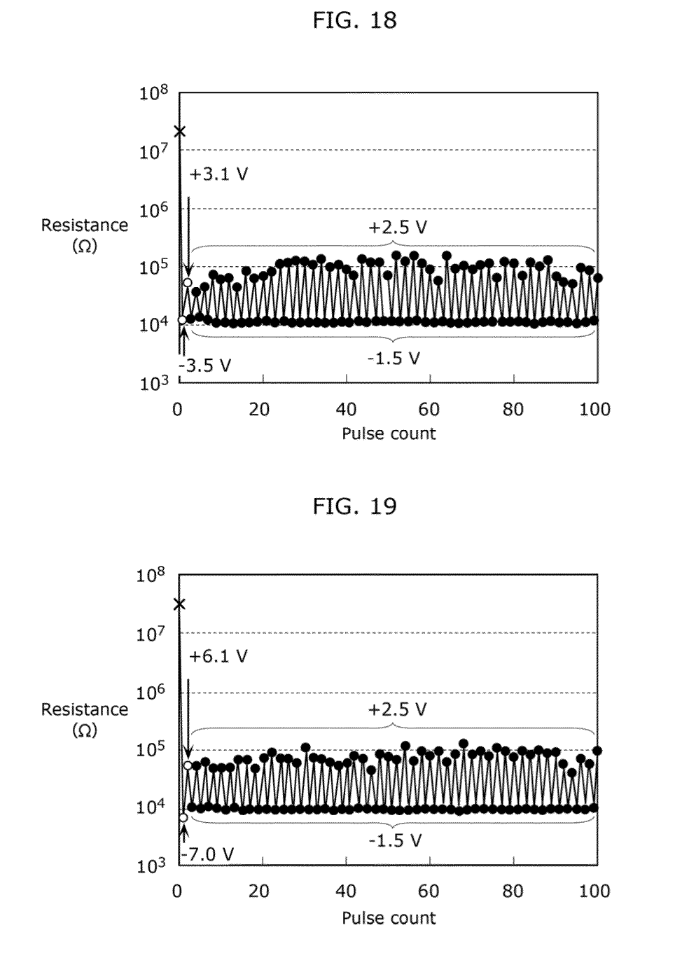

FIG. 18 is a diagram showing resistance change operations of the variable resistance element of the sample 3. Assuming that the load resistor 6 is connected in series, the results in the case where a load resistor of 5 kΩ is connected as the load resistor 6 are shown in FIG. 18.

First, −3.5 V was applied across the first electrode 2 and the second electrode 4 of the variable resistance element 10 (sample 3) as a voltage pulse that causes the first electrode to be relatively negative, to perform an initial breakdown operation. As a result, the resistance value of the variable resistance element 10 (sample 3) decreased from 20 MΩ to 14 kΩ.

Following this, +3.1 V was applied across the first electrode 2 and the second electrode 4 as a voltage pulse that causes the first electrode to be relatively positive, as a result of which the resistance value increased to 54 kΩ.

After this, −1.5 V and +2.5 V were repeatedly applied as lower voltages, so that the variable resistance element 10 (sample 3) performed operations of repeatedly changing between the low resistance state with the resistance value decreased to about 1.1 kΩ and the high resistance state with the resistance value increased to about 50 to 150 kΩ.

FIG. 19 is a diagram showing resistance change operations of the variable resistance element of the comparative sample 2. Assuming that the load resistor 6 is connected in series, the results in the case where a load resistor of 5 kΩ is connected as the load resistor 6 are shown in FIG. 19 as in FIG. 18.

When −3.5 V same as in the sample 3 was applied across the first electrode 2 and the second electrode 4 of the variable resistance element 20 (comparative sample 2) as a voltage pulse that causes the first electrode to be relatively negative, initial breakdown was unable to be induced. −7.0 V was eventually applied to induce initial breakdown. As a result, the resistance value of the variable resistance element 20 (comparative sample 2) decreased from 33 MΩ to 7 kΩ.

Following this, +6.1 V was applied across the first electrode 2 and the second electrode 4 as a voltage pulse that causes the first electrode to be relatively positive, as a result of which the resistance value increased to 54 kΩ.

After this, −1.5 V and +2.5 V were repeatedly applied as lower voltages, so that the variable resistance element 20 (comparative sample 2) performed operations of repeatedly changing between the low resistance state with the resistance value decreased to about 1.2 kΩ and the high resistance state with the resistance value increased to about 40 to 110 kΩ,

As shown in FIGS. 18 and 19, the variable resistance element 10 (sample 3) and the variable resistance element 20 (comparative sample 2) both operate with comparatively low voltages of −1.5 V (low resistance state) and +2.5 V (high resistance state), in normal operations. However, the magnitude of the voltage necessary for initial breakdown significantly differs between the variable resistance element 10 (sample 3) and the variable resistance element 20 (comparative sample 2). The magnitude of the voltage necessary for initial breakdown is smaller in the variable resistance element 10.

Thus, in the case where such a modification process that reduces the oxygen deficiency of the first tantalum oxide layer is performed on the first tantalum oxide layer when forming the variable resistance element 10 according to the manufacturing method in this embodiment, the voltage and the current upon initial breakdown can be reduced and also stable resistance change operations can be maintained.

As described above, according to the present invention, a method of manufacturing a variable resistance nonvolatile memory element capable of reducing a current upon initial breakdown can be provided. Even when a load resistor (on resistor of a selection transistor or a diode, wiring resistor, or the like) is connected to a variable resistance nonvolatile memory element such as a variable resistance element, there is no need to increase a voltage for an initial breakdown step, so that a high-density memory cell array can be realized without an increase in size of a transistor and the like or an increase in withstand voltage.

The same advantageous effects can be achieved even in the case where the above-mentioned modification process performed on the first tantalum oxide layer to reduce its oxygen deficiency is applied to the variable resistance element 20 shown in FIG. 11. In FIG. 11, the positions of the first electrode 2 and the second electrode 4 are vertically reversed and the positions of the first metal oxide layer 231 and the second metal oxide layer 32 are vertically reversed with respect to the structure in FIG. 1. In such a structure, a modified first metal oxide region of the first metal oxide layer 231 may be present near the interface between the first metal oxide layer 231 and the first electrode 2, or present in the whole first metal oxide layer 231.

Though the method of manufacturing the variable resistance nonvolatile memory element according to the present invention has been described by way of the embodiment, the present invention is not limited to the embodiment. Modifications obtained by applying various changes conceivable by those skilled in the art to the embodiment and any combinations of components in different embodiments are also included in the present invention without departing from the scope of the present invention.

For example, though the modification process of the film of the first metal oxide layer 31 is performed by plasma oxidation in the sputtering apparatus immediately before the film formation of the second metal oxide layer 32 starts according to the present invention, other oxidation processes such as ozone oxidation and thermal oxidation in oxygen atmosphere are also applicable. The method of modification is not limited so long as the film quality of the first metal oxide layer 31 or 231 can be modified to reduce the oxygen deficiency.

Though the above embodiment describes the case where at least one part of the first metal oxide layer 31 is modified to the modified layer having a higher oxygen content atomic percentage (higher resistance) than the first metal oxide layer 31 by reducing the oxygen deficiency of the at least one part of the first metal oxide layer 31 by the modification process of the film of the first metal oxide layer 31 (high resistance layer), the present invention is not limited to this. The intermediate layer having a higher oxygen content atomic percentage (higher resistance) than the first metal oxide layer 31 may be formed on the first metal oxide layer 31 (high resistance layer), with the second metal oxide layer 32 (low resistance layer) being formed on the intermediate layer. In either case, as long as a transition metal oxide layer having a higher oxygen content atomic percentage than the first metal oxide layer 31 (high resistance layer) is formed between the first metal oxide layer 31 (high resistance layer) and the second metal oxide layer 32 (low resistance layer), a steep wall of an oxygen content atomic percentage profile can be provided between the first metal oxide layer 31 (high resistance layer) and the second metal oxide layer 32 (low resistance layer), with it being possible to prevent diffusion of oxygen from the first metal oxide layer 31 (high resistance layer) to the second metal oxide layer 32 (low resistance layer) (i.e. corruption of oxygen content atomic percentage profile). Thus, the advantageous effects of reducing the voltage upon initial breakdown can be achieved.

Though the above embodiment describes the example where a fixed resistor of 5 kΩ is used as the load resistor 6 connected in series with the variable resistance element, the present invention is not limited to this. A current steering element such as a transistor or a diode may equally be used, with its on resistor serving as the load resistor. The current steering element may have threshold voltages respectively in a positive applied voltage region and a negative applied voltage region, and have a nonlinear property of being in a conductive state (on) in the case where the applied voltage has a higher absolute value than the corresponding threshold voltage and in a nonconductive state (off) in the case where the applied voltage is in any other region (in the case where the applied voltage has a lower absolute value than the corresponding threshold). The use of the nonvolatile memory element manufacturing method according to the present invention enables initial breakdown to be performed with a low applied voltage even when the current steering element in the memory cell has a high on resistance. The manufacturing method in the above embodiment is applicable to a memory cell array in which memory cells described above are arranged in an array.

Though the above embodiment describes the case where the metal oxide layer 3 has a stack structure of tantalum oxide, the present invention is not limited to this, as the functional effects of the present invention are not limited to the use of tantalum oxide. For example, the metal oxide layer may be formed of hafnium (Hf) oxide in a stack structure or zirconium (Zr) oxide in a stack structure. In the case where hafnium oxide in a stack structure is employed, it is preferable, when a composition of a first hafnium oxide is expressed as HfOₓ and a composition of a second hafnium oxide is expressed as HfO_{y}, that the followings are satisfied: approximately 0.9≦y≦1.6; approximately 1.8<x<2.0; and the first hafnium oxide has a film thickness not less than 3 nm and not more than 4 nm. Furthermore, in the case where zirconium oxide in a stack structure is employed, it is preferable, when a composition of a first zirconium oxide is expressed as ZrOₓ and a composition of a second zirconium oxide is expressed as ZrO_{y}, that the followings are satisfied: approximately 0.9≦y≦1.4; approximately 1.9<x<2.0; and the first zirconium oxide has a film thickness not less than 1 nm and not more than 5 nm.

Furthermore, in the case where hafnium oxide in a stack structure is employed, a first hafnium oxide layer is formed on the first electrode 2 by a reactive sputtering method with which sputtering is performed in argon gas and oxygen gas, using an Hf target. A second hafnium oxide layer can be formed by exposing the surface of the first hafnium oxide layer to plasma of argon gas and oxygen gas after forming the first hafnium oxide layer. The oxygen content atomic percentage in the first hafnium oxide layer can be easily adjusted by changing the flow rate of oxygen gas to argon gas in reactive sputtering, as in the case of tantalum oxide described above. The temperature of the substrate 1 can be set to an ambient temperature with no particular heating.

In addition, the film thickness of the second hafnium oxide layer can be easily adjusted according to the time of exposure to plasma of argon gas and oxygen gas. In the case where the composition of the first hafnium oxide layer is expressed as HfOₓ and the composition of the second hafnium oxide layer is expressed as HfO_{y}, it is possible to implement stable resistance change characteristics when 0.9≦y≦1.6, 1.8<x<2.0, and the film thickness of the first hafnium oxide layer is not less than 3 nm and not more than 4 nm.

In the case where zirconium oxide in a stack structure is employed, a first zirconium oxide layer is formed on the first electrode 2 by a reactive sputtering method with which sputtering is performed in argon gas and oxygen gas, using a Zr target. A second zirconium oxide layer can be formed by exposing the surface of the first zirconium oxide layer to plasma of argon gas and oxygen gas after forming the first zirconium oxide layer The oxygen content atomic percentage in the first zirconium oxide layer can be easily adjusted by changing the flow rate of oxygen gas to argon gas in reactive sputtering, as in the case of tantalum oxide described above. The temperature of the substrate 1 can be set to an ambient temperature with no particular heating, as described above.

In addition, the film thickness of the second zirconium oxide layer can be easily adjusted according to the time of exposure to plasma of argon gas and oxygen gas. In the case where the composition of the first zirconium oxide layer is expressed as ZrOₓ and the composition of the second zirconium oxide layer is expressed as ZrO_{y}, it is possible to implement stable resistance change characteristics when 0.9≦y≦1.4, 1.9<x<2.0, and the film thickness of the first zirconium oxide layer is not less than 1 nm and not more than 5 nm.

Though the above describes that the transition metal oxide (metal oxide layer 3) as the variable resistance layer may comprise tantalum oxide, hafnium oxide, or zirconium oxide, the present invention is not limited to this. The transition metal oxide layer placed between the upper and lower electrodes may include an oxide layer of tantalum, hafnium, zirconium, or the like as a main variable resistance layer where a resistance change occurs, and may additionally include, for example, a slight amount of other element(s). It is also possible to intentionally include the other element(s) in a small amount, for resistance value fine adjustment and the like. Such cases are also included in the scope of the present invention. For example, by adding nitrogen to the variable resistance layer, the variable resistance layer is increased in resistance value, which contributes to an improved resistance change reaction.

Thus, regarding the variable resistance element in which oxygen-deficient transition metal oxide is used in the variable resistance layer, in the case where the variable resistance layer includes a first region comprising a second oxygen-deficient transition metal oxide having a composition expressed as MO and a second region comprising a first oxygen-deficient transition metal oxide having a composition expressed as MOₓ (where y<x), the first region and the second region may comprise a predetermined impurity (e.g. an additive for resistance value adjustment) in addition to the corresponding transition metal oxide.

There are cases where, when the resistance film is formed by sputtering, a slight amount of element(s) is unintentionally mixed into the resistance film due to residual gas, gas emission from a vacuum vessel wall, or the like. Such cases where a slight amount of element(s) is mixed into the resistance film are also included in the scope of the present invention.

### INDUSTRIAL APPLICABILITY

The present invention is applicable as a method of manufacturing a variable resistance nonvolatile memory element. In particular, the present invention is applicable as a method of manufacturing a variable resistance nonvolatile memory element that operates in bipolar mode of reversibly changing in resistance value according to electrical signals of different polarities and that is used in various electronic appliances such as personal computers and mobile phones.

### REFERENCE SIGNS LIST

1 Substrate
2 First electrode
3, 30 Metal oxide layer
4 Second electrode
5 Power source
6 Load resistor
7 Resist pattern
10, 20 Variable resistance element
31, 231 First metal oxide layer
31a Surface part
32 Second metal oxide layer
120a, 120b, 220c, 220d, 320, 320a 20b 320c First electrode layer
131a, 131b, 331a, 331b, 331c First oxygen-deficient tantalum oxide layer
132a, 132b, 332a, 332b, 332c Second oxygen-deficient tantalum oxide layer
140a, 140b, 240c, 240d, 340, 340a, 340b, 340c Second electrode layer
310a, 310b, 310c Conductive layer
230c, 230d Oxygen-deficient hafnium oxide layer

1-22. (canceled)

23. A method of manufacturing a nonvolatile memory element, the method comprising:
forming a first electrode on a substrate;
forming a high resistance layer on the first electrode, the high resistance layer comprising a transition metal oxide;
modifying at least one part of the high resistance layer to a modified layer by reducing an oxygen deficiency of the at least one part, the modified layer having a higher oxygen content atomic percentage than the high resistance layer;
forming a low resistance layer on the modified layer, the low resistance layer comprising a transition metal oxide having a lower oxygen content atomic percentage than the high resistance layer; and
forming a second electrode on the low resistance layer.

24. The method of manufacturing a nonvolatile memory element according to claim 23,
wherein the modifying includes modifying the whole high resistance layer to the modified layer.

25. The method of manufacturing a nonvolatile memory element according to claim 23,
wherein the modifying includes modifying a part of the high resistance layer to the modified layer, and
the nonvolatile memory element includes a variable resistance layer including: the low resistance layer; the high resistance layer; and the modified layer located between the low resistance layer and the high resistance layer.

26. The method of manufacturing a nonvolatile memory element according to claim 23,
wherein the modifying includes oxidizing the at least one part of the high resistance layer.

27. The method of manufacturing a nonvolatile memory element according to claim 26,
wherein the oxidizing includes plasma oxidizing the at least one part of the high resistance layer.

28. The method of manufacturing a nonvolatile memory element according to claim 23,
wherein the nonvolatile memory element changes between a high resistance state and a low resistance state according to an applied electrical pulse.

29. The method of manufacturing a nonvolatile memory element according to claim 23,
wherein the high resistance layer comprises a tantalum oxide having a composition expressed as TaOₓ where 2.1≦x, and
the low resistance layer comprises a tantalum oxide having a composition expressed as TaO_{y} where 0.8≦y≦1.9.

30. The method of manufacturing a nonvolatile memory element according to claim 29,
wherein the variable resistance layer has a thickness not less than 5 nm and not more than 1 μm, and
the high resistance layer has a thickness not less than 1 nm and not more than 8 nm.

31. The method of manufacturing a nonvolatile memory element according to claim 23,
wherein the first electrode has a flat surface with no projection of 2 nm or larger, in an interface of the first electrode with the high resistance layer or the modified layer.

32. The method of manufacturing a nonvolatile memory element according to claim 31,
wherein the first electrode comprises platinum with a film thickness not less than 1 nm and not more than 8 nm.

33. The method of manufacturing a nonvolatile memory element according to claim 31,
wherein the first electrode comprises iridium.

34. The method of manufacturing a nonvolatile memory element according to claim 23,
wherein the nonvolatile memory element is manufactured to further include a current steering element that is electrically connected to the first electrode or the second electrode.

35. The method of manufacturing a nonvolatile memory element according to claim 34,
wherein the current steering element is a transistor.

36. The method of manufacturing a nonvolatile memory element according to claim 34,
wherein the current steering element is a diode.

37. A method of manufacturing a nonvolatile memory element including: a variable resistance layer that comprises a metal oxide and changes between a high resistance state and a low resistance state according to an applied electrical pulse; and a first electrode and a second electrode that are connected to the variable resistance layer, the method comprising:
forming the first electrode on a substrate;
forming a high resistance layer on the first electrode, the high resistance layer comprising a transition metal oxide having a predetermined oxygen content atomic percentage;
forming an intermediate layer on the high resistance layer, the intermediate layer comprising a transition metal oxide that has an oxygen deficiency reduced from an oxygen deficiency of the transition metal oxide of the high resistance layer and has a higher oxygen content atomic percentage than the high resistance layer;
forming a low resistance layer on the intermediate layer, the low resistance layer comprising a transition metal oxide having a lower oxygen content atomic percentage than the high resistance layer; and
forming the second electrode on the low resistance layer,
wherein the variable resistance layer includes the high resistance layer, the intermediate layer, and the low resistance layer.

38. A nonvolatile memory element comprising:
a variable resistance layer that changes between a high resistance state and a low resistance state according to an applied electrical pulse; and
a first electrode and a second electrode that are connected to the variable resistance layer,
wherein the variable resistance layer includes:
a high resistance layer comprising a transition metal oxide;
a low resistance layer comprising a transition metal oxide having a lower oxygen content atomic percentage than the high resistance layer; and
an intermediate layer located between the high resistance layer and the low resistance layer, and comprising a transition metal oxide having a higher oxygen content atomic percentage than the high resistance layer.
